(19) United States
(12) Patent Application Publication
(10) Pub. No.: US 2026/0090170 A1
(43) Pub. Date: Mar. 26, 2026

(54) DISPLAY PANEL AND ELECTRONIC DEVICE INCLUDING THE SAME

(71) Applicant: Samsung Display Co., Ltd., Yongin-si (KR)

(72) Inventor: Junhyeong Park, Yongin-si (KR)

(21) Appl. No.: 19/336,020

(22) Filed: Sep. 22, 2025

(30) Foreign Application Priority Data
Sep. 24, 2024 (KR) 10-2024-0129423

(51) Int. Cl. H10H 29/49; H01L 25/16; H10H 29/34; H10K 59/131; H10K 59/35; H10K 102/00

(52) U.S. Cl. CPC H10H 29/49; H10H 29/34; H10K 59/1315; H10K 59/353; H10W 90/00; H10K 2102/311

(57) ABSTRACT

A display panel includes a support layer including a lower elastomer layer and a stretch control layer on the lower elastomer layer, the support layer having a display area and a non-display area around the display area, in a plan view, and a display layer including a pixel circuit in the display area of the support layer and a light-emitting element electrically connected to the pixel circuit, wherein the stretch control layer includes an auxetic structure including a first sub-unit structure and a second sub-unit structure having a smaller planar area than the first sub-unit structure, the first sub-unit structure includes a plurality of first sub-unit structures, and the first sub-unit structures are continuously arranged in a first row along a first direction, the second sub-unit structure includes second sub-unit structures, and the second sub-unit structures are continuously arranged in a second row along the first direction.

### CROSS-REFERENCE TO RELATED APPLICATION

This application claims priority to and the benefit of Korean Patent Application No. 10-2024-0129423, filed on Sep. 24, 2024, in the Korean Intellectual Property Office, the entire disclosure of which is incorporated by reference herein.

### BACKGROUND

### 1. Field

One or more embodiments relate to a display panel and an electronic device including the same.

### 2. Description of the Related Art

Generally, with the development of display panels that visually display electrical signals, various display panels with excellent characteristics, such as being thinner and lighter and having lower power consumption, and electronic devices including the display panels, are being introduced. For example, research and development is actively underway on display panels of various structures, such as flexible display panels capable of being folded and/or rolled into a roll shape, and stretchable display panels, as well as electronic devices including the display panels.

### SUMMARY

One or more embodiments of the present disclosure include a display panel that implements an image of excellent quality even when the display panel is stretched, and an electronic device including the display panel. However, embodiments of the present disclosure are only examples, and the scope of the present disclosure is not limited thereto.

Additional aspects will be set forth in part in the description that follows and, in part, will be apparent from the description, or may be learned by practice of embodiments of the present disclosure.

According to one or more embodiments, a display panel includes a support layer including a lower elastomer layer and a stretch control layer on the lower elastomer layer, the support layer having a display area and a non-display area around the display area, in a plan view, and a display layer including a pixel circuit in the display area of the support layer and a light-emitting element electrically connected to the pixel circuit, wherein the stretch control layer includes an auxetic structure including a first sub-unit structure and a second sub-unit structure having a smaller planar area than the first sub-unit structure, the first sub-unit structure includes a plurality of first sub-unit structures, and the plurality of first sub-unit structures are continuously arranged in a first row along a first direction, the second sub-unit structure includes a plurality of second sub-unit structures, and the plurality of second sub-unit structures are continuously arranged in a second row along the first direction, and the first row and the second row are repeatedly arranged along a second direction crossing the first direction.

In one or more embodiments, the auxetic structure may have a negative Poisson's ratio.

In one or more embodiments, each of the first sub-unit structure and the second sub-unit structure may have a concave polygonal shape.

In one or more embodiments, each of the first sub-unit structure and the second sub-unit structure may have a re-entrant shape.

In one or more embodiments, the first sub-unit structure and the second sub-unit structure may be alternately arranged relative to each other with respect to the first direction.

In one or more embodiments, the first sub-unit structure has a first horizontal length in the first direction and a first vertical length in the second direction, the second sub-unit structure has a second horizontal length in the first direction and a second vertical length in the second direction, and the first vertical length may be greater than the second vertical length.

In one or more embodiments, the first horizontal length may be equal to the second horizontal length.

In one or more embodiments, the second sub-unit structure may include a first divided region and a second divided region that are symmetrical to each other with respect to an imaginary central line extending along the second direction and located at a center of the second sub-unit structure.

In one or more embodiments, a sum of the first vertical length and the length of the imaginary central line may be equal to the first horizontal length.

In one or more embodiments, the auxetic structure may be formed such that a unit structure including a combination of the first sub-unit structure and the second sub-unit structure is repeatedly arranged, and the unit structure may include the first sub-unit structure arranged in an n^{th} row and an m^{th} column, the second divided region of the second sub-unit structure arranged in an (n+1)^{th} row and an (m−1)^{th} column, and the first divided region of the second sub-unit structure arranged in the (n+1)^{th} row and an (m+1)^{th} column.

In one or more embodiments, the unit structure may have a third horizontal length in the first direction and a third vertical length in the second direction, and the third horizontal length and the third vertical length may be in a ratio of 1:1.

In one or more embodiments, the auxetic structure may include a plurality of openings and a boundary pattern forming a boundary between the plurality of openings.

In one or more embodiments, the boundary pattern of the auxetic structure may have a modulus of at least 3 GPa.

In one or more embodiments, the lower elastomer layer is in the plurality of openings.

In one or more embodiments, in a plan view, the light-emitting element overlaps a center of each of the plurality of openings.

In one or more embodiments, the plurality of openings may include a first opening and a second opening having different planar areas from each other, the first sub-unit structure may have a closed line shape including the first opening, and the second sub-unit structure may have a closed line shape including the second opening.

In one or more embodiments, in a plan view, the light-emitting element may overlap the first opening.

In one or more embodiments, the display area may include a pixel region where the light-emitting element is arranged, and a connection region around the pixel region and in which a connection wire is arranged to connect adjacent pixel circuits, and the connection wire may be stretchable.

In one or more embodiments, in a plan view, the pixel region may overlap the first opening, and the connection region may overlap the second opening and a partial region of the first opening, the partial region excluding the pixel region.

In one or more embodiments, the display panel may further include a gate driving circuit arranged in the non-display area of the support layer, configured to transmit a gate signal to the pixel circuit, and including a plurality of stages, wherein the plurality of stages of the gate driving circuit may be arranged to overlap the plurality of openings, respectively.

In one or more embodiments, the plurality of openings may include a dummy opening arranged outside the gate driving circuit.

In one or more embodiments, the display panel may further include an upper elastomer layer arranged on the display layer and covering the light-emitting element.

In one or more embodiments, the support layer may further include an auxiliary elastomer layer between the stretch control layer and the display layer.

According to one or more embodiments, an electronic device includes a display panel, and a lower cover forming an exterior of the display panel and having an opening exposing a portion of the display panel to a front surface of the electronic device, wherein the display panel includes a support layer including a lower elastomer layer and a stretch control layer on the lower elastomer layer, and the support layer having a display area and a non-display area around the display area, in a plan view, and a display layer including a pixel circuit in the display area of the support layer and a light-emitting element electrically connected to the pixel circuit, wherein the stretch control layer includes an auxetic structure including a first sub-unit structure and a second sub-unit structure having a smaller planar area than the first sub-unit structure, the first sub-unit structure includes a plurality of first sub-unit structures, and the plurality of first sub-unit structures are continuously arranged in a first row in a first direction, the second sub-unit structure includes a plurality of second sub-unit structures, and the plurality of second sub-unit structures are continuously arranged in a second row in the first direction, and the first row and the second row are repeatedly arranged in a second direction crossing the first direction.

### BRIEF DESCRIPTION OF THE DRAWINGS

The above and other aspects and features of embodiments of the present disclosure will be more apparent from the following description taken in conjunction with the accompanying drawings, in which:

FIG. 1A is a perspective view schematically showing an electronic device according to one or more embodiments;

FIG. 1B is a block diagram schematically showing an electronic device according to one or more embodiments;

FIG. 2 is a perspective view schematically showing a display panel according to one or more embodiments;

FIG. 3A is a perspective view showing a state in which a display panel according to a comparative example expands in a first direction;

FIG. 3B is a perspective view showing a state in which a display panel according to one or more embodiments expands in the first direction;

FIG. 3C is a perspective view showing a state in which a display panel according to one or more embodiments expands in the first direction and a second direction crossing the first direction;

FIG. 4 is a plan view schematically showing a display panel according to one or more embodiments;

FIG. 5A is a plan view schematically showing the arrangement of pixels before stretching of a display panel according to one or more embodiments;

FIGS. 5B and 5C are each a plan view schematically showing the arrangement of pixels after stretching of a display panel according to one or more embodiments;

FIG. 6A is a cross-sectional view schematically showing a portion of a display panel according to one or more embodiments;

FIG. 6B is a cross-sectional view schematically showing a portion of a display panel according to another embodiment;

FIGS. 7A-7C are each an equivalent circuit diagram of a pixel of a display panel according to one or more embodiments;

FIGS. 8A and 8B are each a cross-sectional view schematically showing a light-emitting element of a display panel according to one or more embodiments;

FIG. 9 is a plan view schematically showing a stretch control layer of a display panel according to one or more embodiments;

FIG. 10 is an enlarged plan view schematically showing a portion of a stretch control layer of a display panel according to one or more embodiments;

FIG. 11 is a plan view schematically showing a display panel according to one or more embodiments;

FIG. 12 is a cross-sectional view schematically showing a display panel according to one or more embodiments; and

FIGS. 13A-13G are each a perspective view schematically showing embodiments of an electronic device including a display apparatus according to one or more embodiments.

### DETAILED DESCRIPTION

Reference will now be made in detail to embodiments of the present disclosure, examples of which are illustrated in the accompanying drawings, wherein like reference numerals refer to like elements throughout the present specification. In this regard, present embodiments may have different forms and should not be construed as being limited to the descriptions set forth herein. Accordingly, embodiments are merely described below, by referring to the figures, to explain aspects and features of embodiments of the present disclosure. As used herein, the term “and/or” includes any and all combinations of one or more of the associated listed items. Throughout the present disclosure, the expression “at least one of a, b or c” indicates only a, only b, only c, both a and b, both a and c, both b and c, all of a, b, and c, or variations thereof.

Various modifications may be applied to the present embodiments, and embodiments of the present disclosure will be illustrated in the drawings and described in the detailed description section. The effect, aspects, and features of the present disclosure, and a method to achieve the same, will be clearer referring to the detailed descriptions below with the drawings. However, the present embodiments may be implemented in various forms, not by being limited to the embodiments presented below.

Hereinafter, embodiments of the present disclosure will be described in detail with reference to the accompanying drawings, and in the description with reference to the drawings, the same or corresponding components are indicated by the same reference numerals and redundant descriptions thereof are omitted.

In the following embodiments, it will be understood that although the terms “first,” “second,” etc. may be used herein to describe various components, these components should not be limited by these terms. These terms are only used to distinguish one component from another.

In the following embodiments, the expression of singularity in the present specification includes the expression of plurality unless clearly specified otherwise in context.

In the following embodiment, it will be further understood that the terms “comprises” and/or “comprising” used herein specify the presence of stated features or components, but do not preclude the presence or addition of one or more other features or components.

In the following embodiment, it will be understood that when a layer, region, or component is referred to as being “formed on” another layer, region, or component, it can be directly or indirectly formed on the other layer, region, or component. That is, for example, intervening layers, regions, or components may be present.

Sizes of components in the drawings may be exaggerated for convenience of explanation. In other words, because sizes and thicknesses of components in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

It will be understood that when a layer, region, or component is referred to as being “connected to” another layer, region, or component, it can be directly or indirectly connected to the other layer, region, or component. That is, for example, intervening layers, regions, or components may be present. For example, in the present specification, when a layer, region, or component is electrically connected to another layer, region, or component, the layers, regions, or components may not only be directly electrically connected, but may also be indirectly electrically connected via another layer, region, or component therebetween.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

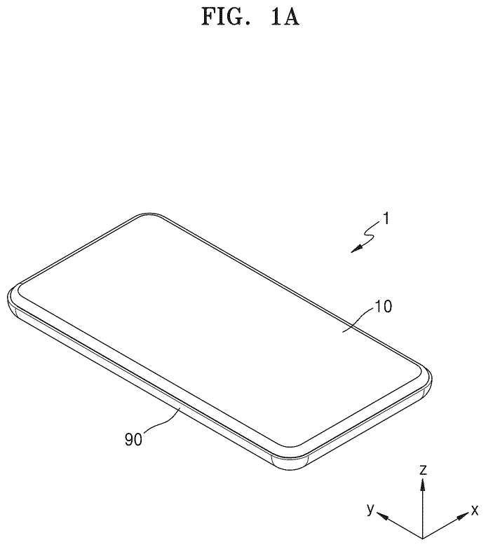

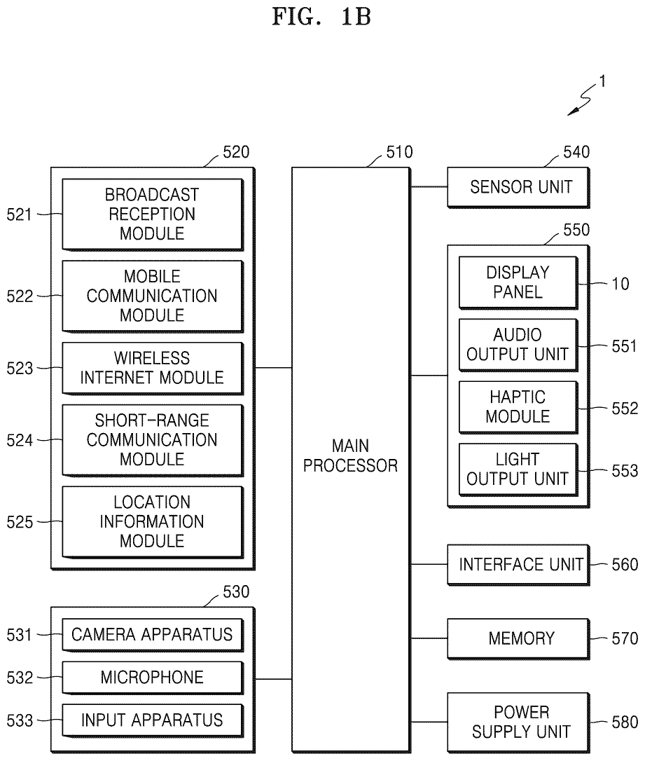

FIG. 1A is a perspective view schematically showing an electronic device 1 according to one or more embodiments, and FIG. 1B is a block diagram schematically showing the electronic device 1 according to one or more embodiments.

Referring to FIGS. 1A and 1B, the electronic device 1 including a display panel 10 according to one or more embodiments is an apparatus that displays moving images and/or still images, and may be used as display screens of various products such as televisions, laptops monitors, billboards, and/or Internet of Things (IoT) devices, as well as portable electronic devices such as mobile phones, smartphones, tablet personal computers (table PCs), mobile communication terminals, electronic organizers, electronic books, portable multimedia players (PMPs), navigation devices, and/or ultra mobile PCs (UMPCs). The electronic device 1 according to one or more embodiments may be used in a wearable device such as a smart watch, a watch phone, a glasses-type display, and/or a head mounted display (HMD). The electronic device 1 according to one or more embodiments may be used as an instrument panel of vehicles, a center information display (CID) arranged on the center fascia or dashboard of vehicles, a room mirror display in place of side-view mirrors of vehicles, and/or a display arranged at the rear side of a front seat as an entertainment for a rear seat of vehicles.

FIG. 1A shows that the electronic device 1 according to one or more embodiments is used as a smartphone. The electronic device 1 may include the display panel 10 and a lower cover 90 arranged under the display panel 10. The electronic device 1 may include a cover window covering a top surface of the display panel 10.

The lower cover 90 may form an exterior of the electronic device 1 and may have an opening exposing a portion of the display panel 10 to a front surface of the electronic device 1. The lower cover 90 is formed to have an open surface corresponding to the display panel 10 and may be assembled with the display panel 10. The lower cover 90 may form an exterior of a bottom surface of the electronic device 1, and a display circuit board, a component, a main circuit board, a battery, a driver, etc. may be arranged between the display panel 10 and the lower cover 90. The lower cover 90 may include plastic, metal, or both plastic and metal.

The electronic device 1 may include a main processor 510, a wireless communication unit 520, an input unit 530, a sensor unit 540, an output unit 550, an interface unit 560, a memory 570, and/or a power supply unit 580.

The main processor 510 may control all functions of the electronic device 1. For example, the main processor 510 may output digital video data to a data driver through a display circuit board such that the display panel 10 displays an image. The main processor 510 may receive sensing data from a touch sensor driving unit. The main processor 510 may determine whether there has been a user touch, based on the sensing data, and may execute an operation corresponding to the user's direct touch or proximity touch. The main processor 510 may be an application processor, a central processing unit (CPU), or a system chip, each including an integrated circuit (IC).

A camera apparatus 531 processes an image frame, such as a still image and/or a moving image, obtained by an image sensor in a camera mode, and outputs the processed image frame to the main processor 510. The camera apparatus 531 may include a camera sensor (for example, charge-coupled device (CCD), Complementary Metal-Oxide-Semiconductor (CMOS), etc.), a photo sensor (or an image sensor), and/or a laser sensor. The camera apparatus 531 may be connected to the image sensor and may process an image input to the image sensor.

The wireless communication unit 520 may include a broadcast reception module 521, a mobile communication module 522, a wireless Internet module 523, a short-range communication module 524, and/or a location information module 525.

The broadcast reception module 521 receives a broadcast signal and/or broadcast-related information from an external broadcast management server through a broadcast channel. The broadcast channel may include a satellite channel and/or a terrestrial channel.

The mobile communication module 522 may transceive a wireless signal to and from a base station, an external terminal, and/or a server over a mobile communication network built according to technology standards or communication methods (for example, global system for mobile communication (GSM), code-division multiple access (CDMA), CDMA 2000, enhanced voice-data optimized or enhanced voice-data only (EV-DO), wideband CDMA (WCDMA), high speed downlink packet access (HSDPA), high speed uplink packet access (HSUPA), long-term evolution (LTE), LTE-advanced (LTE-A), etc.) for mobile communication. The wireless signal may include various types of data based on transmission and reception of voice call signals, video call signals, and/or text/multimedia messages.

The wireless Internet module 523 refers to a module for accessing wireless Internet. The wireless Internet module 523 may be configured to transceive a wireless signal in a communication network based on wireless Internet technologies. The wireless Internet technologies include, for example, wireless LAN (WLAN), wireless-fidelity (Wi-Fi), Wi-Fi Direct, Digital Living Network Alliance (DLNA), etc.

The short-range communication module 524 is for short-range communication, and may support short-range communication by using Bluetooth™, radio frequency identification (RFID), Infrared Data Association (IrDA), ultra wideband (UWB), ZigBee, near-field communication (NFC), Wi-Fi, Wi-Fi Direct, and/or wireless universal serial bus (wireless USB) technologies. The short-range communication module 524 may support, through wireless area networks, wireless communication between the electronic device 1 and a wireless communication system, between the electronic device 1 and another electronic apparatus, or between the electronic device and a network where another electronic apparatus (or external server) is located. The wireless area networks may be wireless personal area networks. The other electronic apparatus may be a wearable device that is capable of exchanging data with (or interworking with) the electronic device 1.

The location information module 525 is a module for obtaining the location (or current location) of the electronic device 1, and may include a global positioning system (GPS) module and/or a Wi-Fi module.

The input unit 530 may include an image input unit such as the camera apparatus 531 for inputting an image signal, an audio input unit such as a microphone 532 for inputting an audio signal, and an input apparatus 533 for receiving information from a user.

The camera apparatus 531 processes an image frame of a still image, a moving image, and/or the like, which is obtained by an image sensor, in a video call mode and/or a shooting mode. The processed image frame may be displayed on the display panel 10 or may be stored in the memory 570.

The microphone 532 processes an external audio signal into electrical voice data. The processed voice data may be utilized in various ways depending on a function (or an application) being executed in the electronic device 1.

The main processor 510 may control the operation of the electronic device 1 to correspond to information input through the input apparatus 533. The input apparatus 533 may include a mechanical input means, such as a button, a dome switch, a jot wheel, a jog switch, etc., which is located on a rear surface or a side surface of the electronic device 1, or a touch input means. The touch input means may include a touch screen layer of the display panel 10.

The sensor unit 540 may include at least one sensor that senses information inside the electronic device 1, information about an environment surrounding the electronic device 1, and/or user information, and generates a corresponding sensing signal. Based on the sensing signal, the main processor 510 may control the driving or operation of the electronic device 1 or may perform data processing, a function, and/or an operation, each of which is related to an application installed on the electronic device 1. The sensor unit 540 may include a proximity sensor, an illumination sensor, an acceleration sensor, a magnetic sensor, a gravity sensor (G-sensor), a gyroscope sensor, a motion sensor, an RGB sensor, an infrared (IR) sensor, a fingerprint scan sensor, an ultrasonic sensor, an optical sensor, a battery gauge, an environmental sensor (for example, a barometer, a hygrometer, a thermometer, a radiation detection sensor, a heat detection sensor, a gas detection sensor, etc.), and/or a chemical sensor (for example, an electronic nose, a healthcare sensor, a biometric sensor, etc.).

The output unit 550 is for generating output related to a visual, auditory, and/or tactile sense, and/or the like, and may include the display panel 10, an audio output unit 551, a haptic module 552, and/or a light output unit 553.

The display panel 10 may display (output) information processed by the electronic device 1. For example, the display panel 10 may display execution screen information of an application running on the electronic device 1, or user interface (UI) or graphic user interface (GUI) information according to the execution screen information. The display panel 10 may include a display layer that displays an image, and a touch screen layer that detects a user's touch input. Accordingly, the display panel 10 may function as the input apparatus 533 that provides an input interface between the electronic device 1 and the user, and at the same time, function as the output unit 550 that provides an output interface between the electronic device 1 and the user.

The audio output unit 551 may output audio data received from the wireless communication unit 520 or stored in the memory 570 in a signal reception, a call mode, and/or a recording mode, a voice recognition mode, a broadcast reception mode, etc. The audio output unit 551 may also output an audio signal related to a function (for example, a call signal reception sound, a message reception sound, etc.) performed in the electronic device 1. The audio output unit 551 may include a receiver or a speaker. At least one of the receiver or the speaker may be an audio generation apparatus that is attached to a lower portion of the display panel 10 and outputs audio by vibrating the display panel 10. The audio generation apparatus may be a piezoelectric element or a piezoelectric actuator, each of which contracts and expands according to an electrical signal, or may be an exciter that generates magnetic force by using a voice coil to vibrate the display panel 10.

The haptic module 552 generates various tactile effects that may be felt by a user. The haptic module 552 may provide vibration to a user as a tactile effect. The haptic module 552 may not only transfer a tactile effect through direct contact, but may also be implemented such that a user may feel a tactile effect through a muscle sense such as a finger or an arm.

The light output unit 553 outputs a signal for notifying occurrence of an event by using light from a light source. Examples of the event that occurs in the electronic device 1 may include a message reception, a call signal reception, missed calls, alarms, a schedule notification, an email reception, and/or information reception through an application. The signal output by the light output unit 553 is generated by the electronic device 1 emitting monochromatic or multi-colored light from either a front surface or a rear surface thereof. The signal output may be terminated when the electronic device 1 detects a user's event acknowledgement.

The interface unit 560 serves as a conduit for various types of external devices connected to the electronic device 1. The interface unit 560 may include a wired/wireless headset port, an external charger port, a wired/wireless data part, a memory card port, a port for connecting an apparatus equipped with an identification module, an audio input/output (I/O) port, a video I/O port, and/or an earphone port. In response to an external device being connected to the interface unit 560, the electronic device 1 may perform appropriate control related to the connected external device.

The memory 570 stores data that supports various functions of the electronic device 1. The memory 570 may store a plurality of application programs running on the electronic device 1, data for the operation of the electronic device 1, and commands. At least some of the plurality of application programs may be downloaded from an external server through wireless communication. The memory 570 may store an application for the operation of the main processor 510, and may also temporarily store input/output data, for example, data such as a phonebook, a message, a still image, a moving image, etc. In addition, the memory 570 may store haptic data for various vibration patterns provided to the haptic module 552, and audio data relating to a variety of audio provided to the audio output unit 551. The memory 570 may include a type of storage medium from among a flash memory type, a hard disk type, a solid state disk (SSD) type, a multimedia card micro type, a card type memory (for example, SD or XD memory), random access memory (RAM), static RAM (SRAM), read-only memory (ROM), electrically erasable programmable ROM (EEPROM), programmable ROM (PROM), a magnetic memory, a magnetic disk, and/or an optical disk.

The power supply unit 580 receives external or internal power and supplies the power to each of the components included in the electronic device 1, under control by the main processor 510. The power supply unit 580 may include a battery. In addition, the power supply unit 580 includes a connection port, and the connection port may be configured as an example of the interface unit 560 to which an external charger that supplies power for charging the battery is electrically connected. Alternatively, the power supply unit 580 may be configured to charge the battery wirelessly without using a connection port.

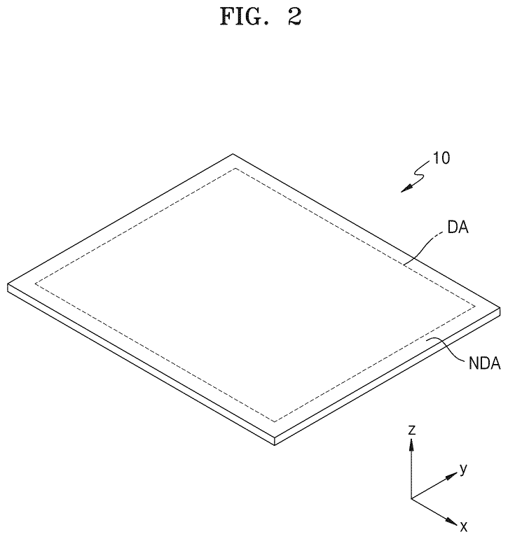

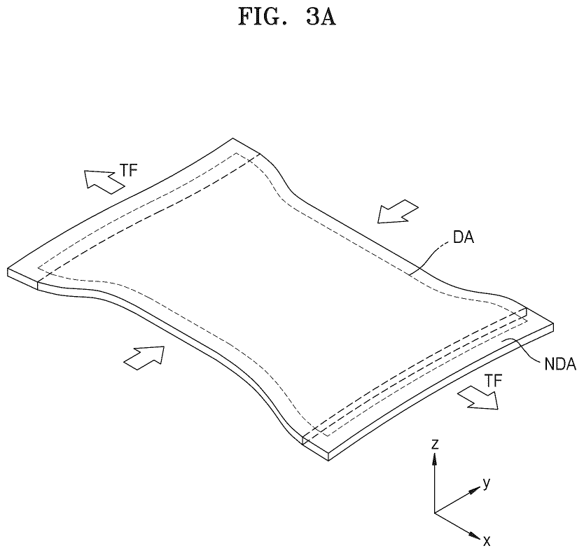

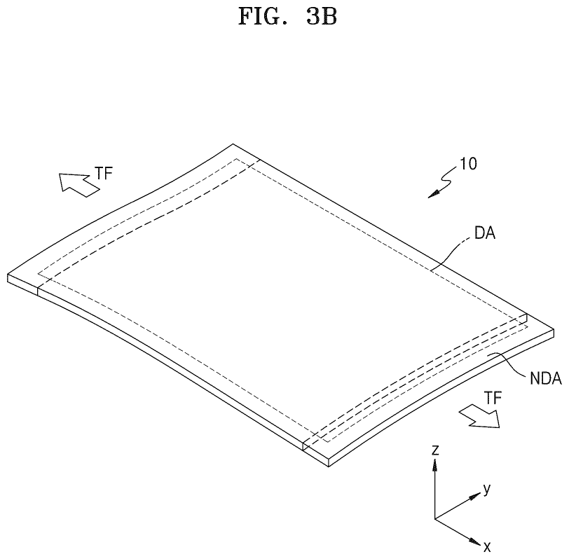

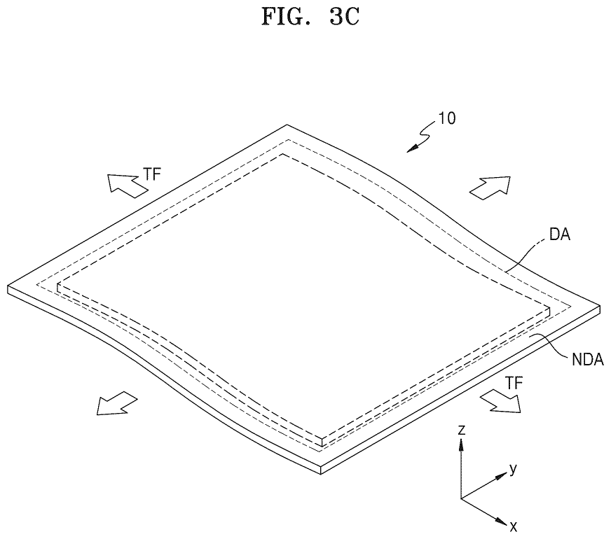

FIG. 2 is a perspective view schematically showing a display panel according to one or more embodiments. FIG. 3A is a perspective view showing a state in which a display panel according to a comparative example expands in a first direction. FIG. 3B is a perspective view showing a state in which a display panel according to one or more embodiments expands in the first direction. FIG. 3C is a perspective view showing a state in which a display panel according to one or more embodiments expands in the first direction and the second direction.

Referring to FIG. 2, the display panel 10 may include a display area DA and a non-display area NDA around an edge or a periphery of the display area DA. The display area DA may include a plurality of pixels. A display panel 10 may provide a certain image by using light emitted from the plurality of pixels. The non-display area NDA may be arranged outside the display area DA. The non-display area NDA may entirely surround the display area DA.

Because the display panel 10 includes a stretchable material, the display panel 10 may expand or contract in various directions. The display panel 10 may expand in a first direction (for example, x direction and/or −x direction) or a second direction (for example, y direction and/or −y direction) due to an external object or an external force applied by a user. When a tensile force TF is applied to the display panel 10 in a longitudinal direction (for example, the second direction), deformation in both the longitudinal direction and a transverse direction (for example, the first direction) may occur in the display panel 10. At this time, a negative ratio between a longitudinal strain and a transverse strain may be defined as Poisson's ratio.

As shown in FIG. 3A, when a tensile force TF in the first direction (for example, x direction and/or −x direction) is applied to a display panel having a general structure, the display panel may be stretched in the first direction (for example, x direction and/or −x direction). However, the display panel may be stretched in the first direction (for example, x direction and/or −x direction) and, at the same time, may contract in the second direction (for example, y direction and/or −y direction). In other words, because the display panel having a general structure as shown in FIG. 3A may have a positive Poisson's ratio because signs of a longitudinal strain and a transverse strain are different from each other.

At this time, when the display panel as shown in FIG. 3A is stretched in the first direction (for example, x direction and/or −x direction), the display panel contracts in the second direction (for example, y direction and/or −y direction), and thus, wrinkles may appear on the display panel. In addition, when the display panel contracts in the second direction (for example, y direction and/or −y direction), the arrangement of pixels arranged on the display panel may become distorted, which may lead to distortion in an image implemented by the display panel.

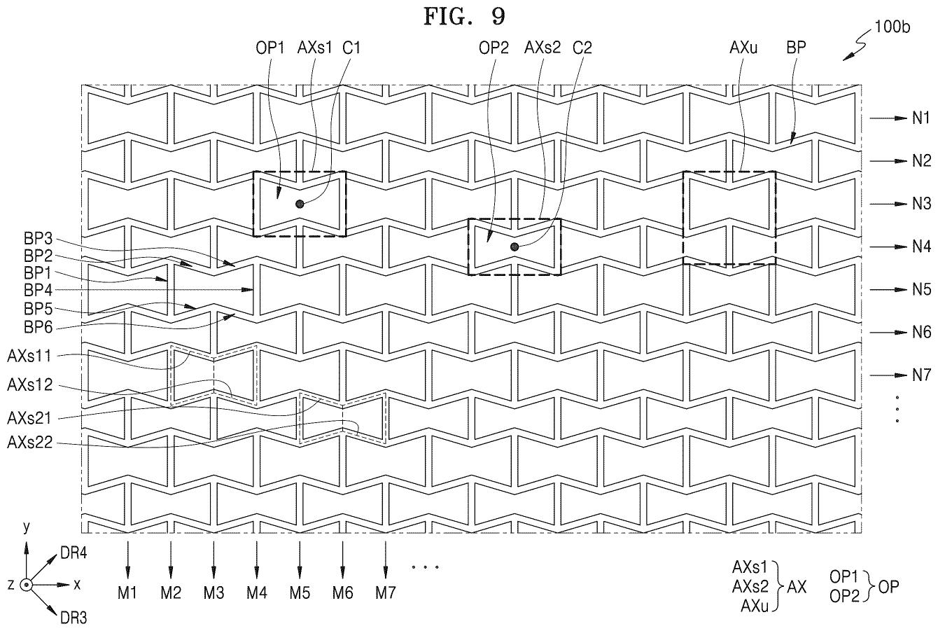

In contrast, referring to FIGS. 3B and 3C, the display panel 10 according to one or more embodiments includes a structure having a negative Poisson's ratio and thus may implement a high-quality image even when stretched. In detail, the display panel 10 according to one or more embodiments may include an auxetic structure AX (FIG. 9) having a negative Poisson's ratio. In the auxetic structure AX (FIG. 9), signs of a longitudinal strain and a transverse strain may be the same.

When the tensile force TF in the first direction (for example, x direction and/or −x direction) is applied to the display panel 10, the display panel 10 including the auxetic structure AX (FIG. 9) described below may be stretched in the first direction (for example, x direction and/or −x direction) and may be stretched in the second direction (for example, y direction and/or −y direction). For example, although the display panel 10 as shown in FIG. 3B is stretched in the first direction (for example, x direction and/or −x direction), the display panel 10 may not contract in the second direction (for example, y direction and/or −y direction) because the display panel 10 includes the auxetic structure AX (FIG. 9) having a negative Poisson's ratio. Alternatively, because the display panel 10 as shown in FIG. 3C includes the auxetic structure AX (FIG. 9), the display panel 10 may be stretched in the first direction (for example, x direction and/or −x direction) and, at the same time, may be stretched in the second direction (for example, y direction and/or −y direction).

In other words, the display panel 10 according to one or more embodiments may be stretched in a direction in which a tensile force TF is applied, and may be stretched in a direction perpendicular to the direction in which the tensile force TF is applied. Even when the display panel 10 including the auxetic structure AX (FIG. 9) is stretched in a specific direction, the display panel 10 does not contract in a direction perpendicular to the specific direction, and thus, wrinkles may not appear on the display panel 10. In addition, the display panel 10 as shown in FIGS. 3B and 3C may maintain the arrangement of pixels at regular intervals, thereby enabling implementation of an image of high quality (e.g., excellent quality) even when stretched.

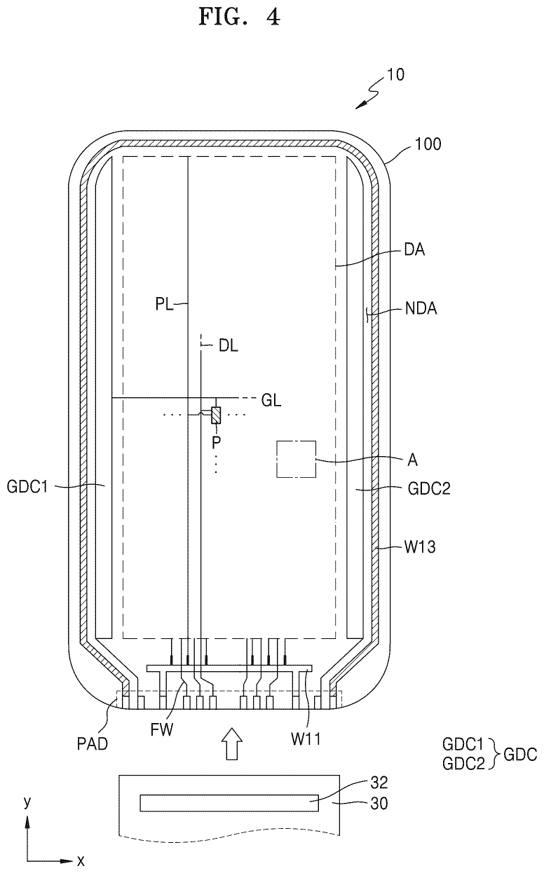

FIG. 4 is a plan view schematically showing the display panel 10 according to one or more embodiments.

Referring to FIG. 4, various components of the display panel 10 are arranged on a substrate 100. The substrate 100 may include the display area DA and the non-display area NDA surrounding the display area DA. The display area DA may be covered with a sealing member and protected from external air and/or moisture.

Pixels P are arranged in the display area DA of the substrate 100. Each of the pixels P may display an image by using light emitted from a light-emitting element such as a light-emitting diode. Each of the light-emitting diodes may emit, for example, red light, green light, and/or blue light.

Each light-emitting diode may be electrically connected to a pixel circuit, and each of the pixel circuits may include transistors and a storage capacitor. Each pixel circuit may be electrically connected to a peripheral circuit and/or peripheral wires, which are arranged in the non-display area NDA. The peripheral circuits arranged in the non-display area NDA may include a gate driving circuit GDC and a terminal unit PAD. The peripheral wires may include a driving voltage supply wire W11, a common voltage supply wire W13, and a fan-out wire FW.

The gate driving circuit GDC may include drivers for providing an electrical signal to a gate electrode of each of the transistors electrically connected to light-emitting elements. In detail, the gate driving circuit GDC may be configured to apply a scan signal to each of the pixel circuits corresponding to the pixels P through a gate line GL.

The gate driving circuit GDC may include a first gate driving circuit GDC1 and a second gate driving circuit GDC2, which are respectively arranged at both side of the display area DA. The second gate driving circuit GDC2 may be arranged opposite to the first gate driving circuit GDC1 with respect to the display area DA and may be approximately parallel to the first gate driving circuit GDC1. Some of the pixel circuits may be electrically connected to the first gate driving circuit GDC1, and the others may be electrically connected to the second gate driving circuit GDC2. In one or more embodiments, the second gate driving circuit GDC2 may be omitted.

The terminal unit PAD may be arranged on one side of the substrate 100. The terminal unit PAD is exposed without being covered by an insulating layer and is thus connected to a display circuit board 30. A display driving unit 32 may be arranged on the display circuit board 30. The display driving unit 32 may generate a control signal to be transmitted to the first gate driving circuit GDC1 and the second gate driving circuit GDC2. The display driving unit 32 may generate a data signal, and the generated data signal may be transmitted to the pixel circuits of the pixels P through the fan-out wire FW and a data line DL connected to the fan-out wire FW.

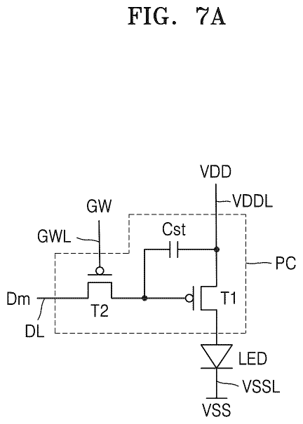

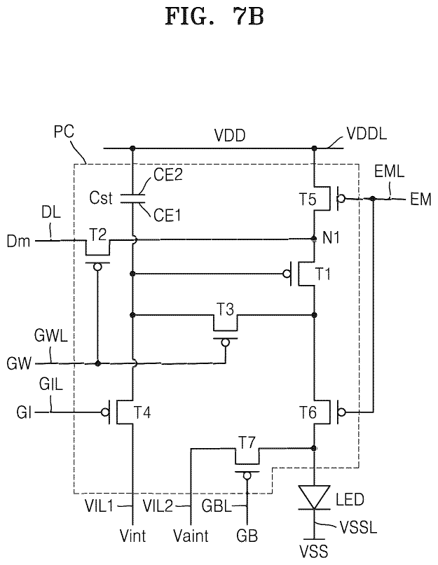

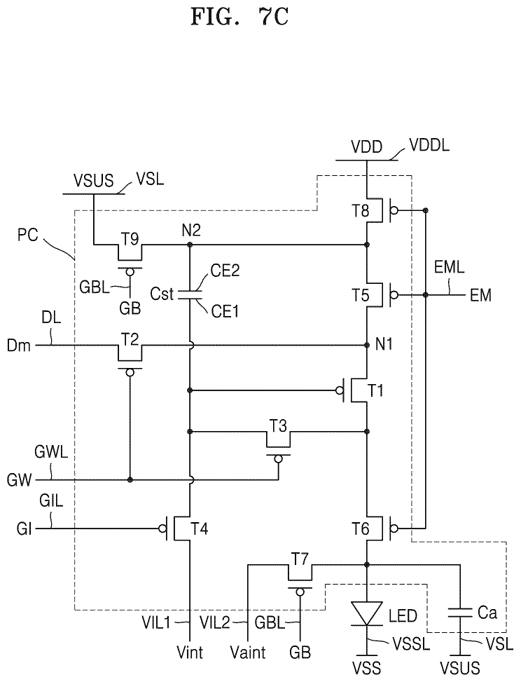

The display driving unit 32 may supply a first power voltage VDD (FIG. 7A) to the driving voltage supply wire W11 and may supply a second power voltage VSS (FIG. 7A) to the common voltage supply wire W13. The first power voltage VDD (FIG. 7A) may be applied to a pixel circuit of a pixel P through a driving voltage line PL connected to the driving voltage supply wire W11, and the second power voltage VSS (FIG. 7A) may be connected to the common voltage supply wire W13 and may be applied to an opposite electrode of a light-emitting element. The driving voltage supply wire W11 may extend on the lower side of the display area DA in the x direction. The common voltage supply wire W13 has a loop shape with one side open and thus may partially surround the display area DA.

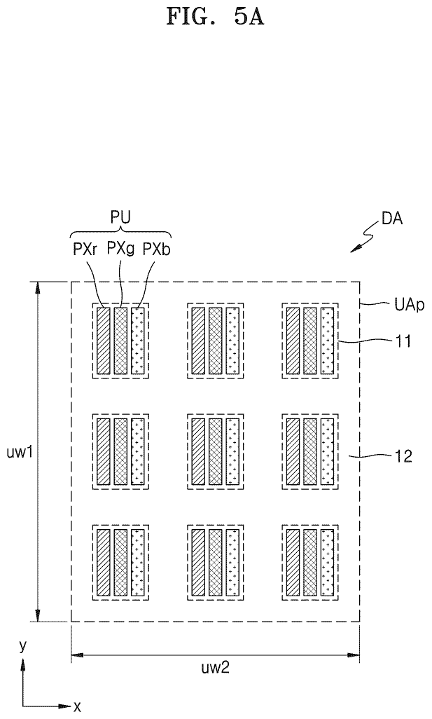

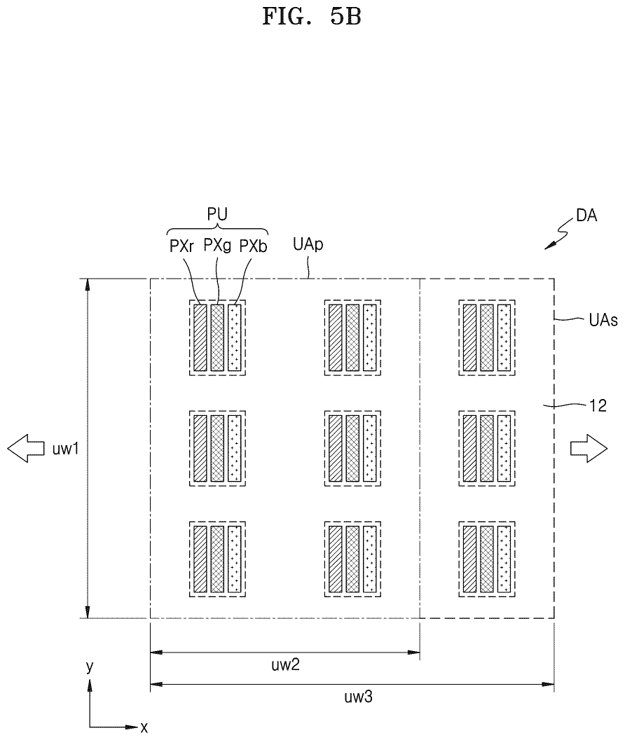

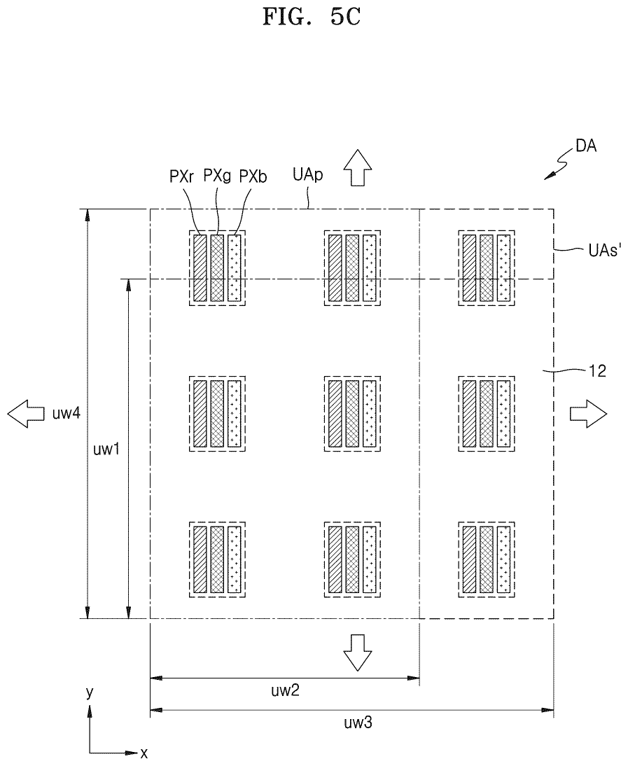

FIG. 5A is a plan view schematically showing the arrangement of pixels before stretching of a display panel according to one or more embodiments. FIGS. 5B and 5C are each a plan view schematically showing the arrangement of pixels after stretching of a display panel according to one or more embodiments.

Referring to FIG. 5A, a red pixel PXr, a green pixel PXg, and a blue pixel PXb may be arranged in the display area DA of the display panel 10. The display area DA may include a pixel region 11 and a connection region 12 outside the pixel region 11. The red pixel PXr, the green pixel PXg, and the blue pixel PXb may be arranged in the pixel region 11. The red pixel PXr, the green pixel PXg, and the blue pixel PXb may form one pixel unit PU. Pixel units PU may be repeatedly arranged in the display area DA.

Connection wires electrically connecting adjacent pixels may be arranged in the connection region 12. When the display panel 10 is stretched, the connection region 12 may be stretched relatively more than the pixel region 11. In one or more embodiments, the connection wires arranged in the connection region 12 may include a material that has both desired elasticity and electrical characteristics (e.g., excellent elasticity and electrical characteristics). For example, the connection wires arranged in the connection region 12 may include a metal nanostructure and an elastic polymer. Alternatively, the connection wires arranged in the connection region 12 may include liquid metal. Pixel regions 11 may be arranged at certain intervals along the first direction (for example, x direction) and the second direction (for example, y direction).

When the display panel 10 is in its original, unstretched state, a region where the 3×3 pixel region 11 is arranged may be defined as a unit region UAp before stretching. The unit region UAp before stretching may have a second unit width uw2 in the first direction (for example, x direction) and may have a first unit width uw1 in the second direction (for example, y direction).

Referring to FIGS. 5B and 5C, the display panel 10 may be stretched in the first direction (for example, x direction). As described above, when the display panel having a general structure is stretched in the first direction (for example, x direction), the display panel may contract in the second direction (for example, y direction). In other words, the width of the unit region after stretching, in the second direction (for example, y direction), may be smaller than the first unit width uw1. The pixel regions 11 arranged on such a display panel may not be arranged at certain intervals, and in a specific portion, spacing may decrease, or the arrangement of the pixel regions 11 may become distorted.

In contrast, when the display panel 10 including the auxetic structure AX (FIG. 9) described below is stretched in the first direction (for example, x direction), the display panel 10 may not contract in the second direction (for example, y direction). For example, even when the display panel 10 as shown in FIG. 5B is stretched in the first direction (for example, x direction), deformation in the second direction (for example, y direction) may not occur. Alternatively, even when the display panel 10 as shown in FIG. 5C is stretched in the first direction (for example, x direction), the display panel 10 may be also stretched in the second direction (for example, y direction).

In a state where the display panel 10 is stretched, a region where the 3×3 pixel region 11 is arranged may be defined as a unit region UAs or UAs' after stretching. Referring to FIG. 5B, the unit region UAs after stretching may have a third unit width uw3 greater than the second unit width uw2 in the first direction (for example, x direction) and may have the first unit width uw1 in the second direction (for example, y direction). Even when the display panel 10 is stretched in the first direction (for example, x direction), contraction in the second direction (for example, y direction) does not occur, and thus, spacing between the pixel regions 11 may uniformly increase in a horizontal direction, allowing the arrangement of the pixel regions 11 to be stably maintained.

Referring to FIG. 5C, the unit region UAs' after stretching may have the third unit width uw3 greater than the second unit width uw2 in the first direction (for example, x direction) and may have a fourth unit width uw4 greater than the first unit width uw1 in the second direction (for example, y direction). The display panel 10 is stretched in the first direction (for example, x direction) and concurrently (e.g., simultaneously) stretched in the second direction (for example, y direction), and thus, spacing between the pixel regions 11 may uniformly increase in both directions, allowing the arrangement of the pixel regions 11 to be stably maintained.

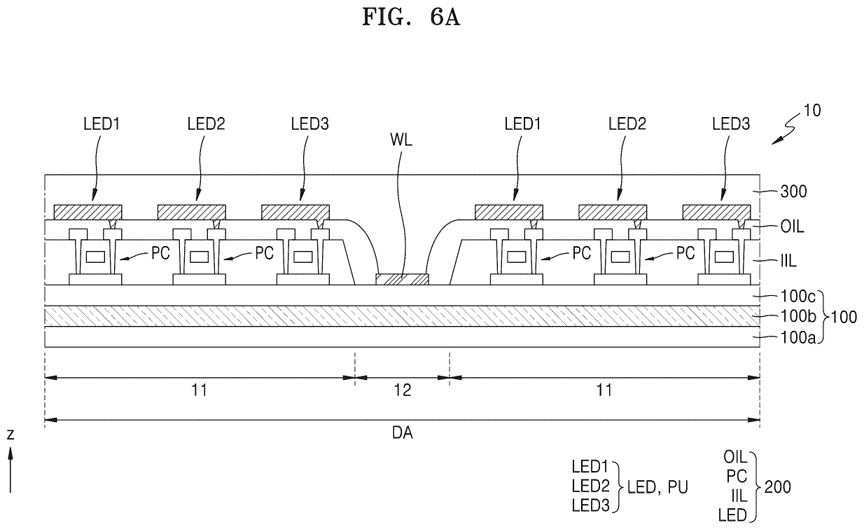

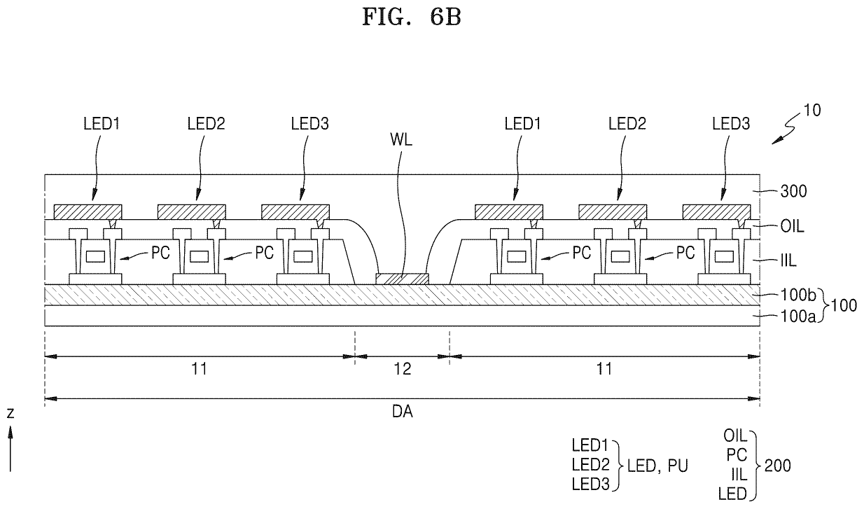

FIG. 6A is a cross-sectional view schematically showing a portion of a display panel according to one or more embodiments. FIG. 6B is a cross-sectional view schematically showing a portion of a display panel according to another embodiment.

Referring to FIGS. 6A and 6B, the display area DA may include the pixel region 11 and the connection region 12, and the connection region 12 may connect the pixel regions 11 arranged adjacent to each other. The pixel region 11 may include a light-emitting element LED, a circuit, for example, a pixel circuit PC, for driving the light-emitting element LED. The connection region 12 may include a connection wire WL electrically connected to the pixel circuits PC arranged in each of the pixel regions 11.

The pixel region 11 and the connection region 12 may be formed on a support layer 100. In other words, the support layer 100 may define each of the pixel region 11 and the connection region 12. The light-emitting element LED and the pixel circuit PC may be arranged in the pixel region 11 of the support layer 100, and the connection wire WL may be arranged in the connection region 12 of the support layer 100.

In one or more embodiments, as shown in FIG. 6A, the support layer 100 may include a lower elastomer layer 100a, a stretch control layer 100b, and an auxiliary elastomer layer 100c. The lower elastomer layer 100a, the stretch control layer 100b, and the auxiliary elastomer layer 100c may be sequentially stacked. In other words, the auxetic structure AX (FIG. 9) of the stretch control layer 100b may be embedded in an elastomer including the lower elastomer layer 100a and the auxiliary elastomer layer 100c. Accordingly, the auxetic structure AX (FIG. 9) of the stretch control layer 100b may not be in direct contact with a display layer 200, and the auxiliary elastomer layer 100c may be in direct contact with the display layer 200.

In another embodiment, as shown in FIG. 6B, the support layer 100 may include only the lower elastomer layer 100a and the stretch control layer 100b. The stretch control layer 100b may be arranged on the lower elastomer layer 100a. In other words, the auxetic structure AX (FIG. 9) of the stretch control layer 100b may be embedded in an upper surface of the lower elastomer layer 100a. Accordingly, the auxetic structure AX (FIG. 9) of the stretch control layer 100b may be in direct contact with the display layer 200.

The stretch control layer 100b may include the auxetic structure AX (FIG. 9). The auxetic structure AX (FIG. 9) is a structure having a negative Poisson's ratio, and when the display panel 10 is stretched in the first direction (for example, x direction), the stretch control layer 100b may prevent the display panel 10 from contracting in the second direction (for example, y direction). Likewise, when the display panel 10 is stretched in the second direction (for example, y direction), the stretch control layer 100b may prevent the display panel 10 from contracting in the first direction (for example, x direction). The auxetic structure AX (FIG. 9) may include a plurality of openings and a boundary pattern forming a boundary between the plurality of openings, and the plurality of openings may be occupied by the lower elastomer layer 100a and/or the auxiliary elastomer layer 100c. The auxetic structure is described in detail with reference to FIG. 9.

The lower elastomer layer 100a and the auxiliary elastomer layer 100c may absorb stress that may occur during stretching of the display panel 10. In detail, stress that may be concentrated on the boundary pattern of the auxetic structure AX (FIG. 9) of the lower elastomer layer 100a and the auxiliary elastomer layer 100c during stretching of the display panel 10 may be prevented from being transmitted to the display layer 200.

Each of the lower elastomer layer 100a and the auxiliary elastomer layer 100c may include an elastic polymer. For example, each of the lower elastomer layer 100a and the auxiliary elastomer layer 100c may include thermoplastic polyurethane, silicone, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, polydimethylsiloxane (PDMS), and/or ecoflex.

In one or more embodiments, the lower elastomer layer 100a and the auxiliary elastomer layer 100c may include the same material and may be integrally formed as a single body. However, the present disclosure is not limited thereto, and the lower elastomer layer 100a and the auxiliary elastomer layer 100c may include different materials from each other.

The display layer 200 may be arranged in the pixel region 11 of the support layer 100. The display layer 200 may include an inorganic insulating layer IIL, the pixel circuit PC, an organic insulating layer OIL, and the light-emitting element LED. The pixel circuit PC may be arranged on the support layer 100, and the inorganic insulating layer IIL may be arranged between electrodes included in the pixel circuit PC. The organic insulating layer OIL may be arranged on the inorganic insulating layer IIL to cover the pixel circuit PC. The light-emitting element LED may be arranged on the organic insulating layer OIL and may be electrically connected to the corresponding pixel circuit PC. The inorganic insulating layer IIL may include an inorganic insulating material such as silicon nitride and/or silicon oxide, and the organic insulating layer OIL may include an organic insulating material such as polyimide.

In one or more embodiments, one pixel unit PU may be arranged in one pixel region 11. The pixel unit PU may include the red pixel PXr (FIG. 5A), the green pixel PXg (FIG. 5A), and the blue pixel PXb (FIG. 5A), as described above. The red pixel PXr (FIG. 5A) may include a first light-emitting diode LED1, the green pixel PXg (FIG. 5A) may include a second light-emitting diode LED2, and the blue pixel PXb may include a third light-emitting diode LED3. For example, the first light-emitting diode LED1 may emit red light, the second light-emitting diode LED2 may emit green light, and the third light-emitting diode LED3 may emit blue light. In one or more embodiments, the light-emitting element LED may also emit white light.

The connection wire WL may be arranged in the connection region 12 of the support layer 100. In one or more embodiments, as shown in FIG. 6A, the connection wire WL may be arranged on the support layer 100. In another embodiment, the connection wire WL may be arranged in the support layer 100. The connection wire WL may include a material that has both suitable elasticity and electrical characteristics (e.g., excellent elasticity and electrical characteristics).

The organic insulating layer OIL may be arranged in the connection region 12 of the support layer 100. In one or more embodiments, the organic insulating layer OIL arranged in the connection region 12 may be a portion of the organic insulating layer OIL that is arranged in the pixel region 11 and extends into the connection region 12. When the display panel 10 is stretched, the connection region 12 may undergo relatively greater deformation than the pixel region 11. Accordingly, the connection region 12 may not include a layer including an inorganic insulating material, which is prone to crack formation, unlike the pixel region 11.

In one or more embodiments, an upper elastomer layer 300 may be arranged on the light-emitting element LED. The upper elastomer layer 300 may be arranged in both the pixel region 11 and the connection region 12. In other words, the upper elastomer layer 300 may be arranged to entirely cover the display area DA. The upper elastomer layer 300 may absorb stress that may occur when the display panel 10 is stretched. In detail, the upper elastomer layer 300 may prevent stress, which may occur when the display panel 10 is stretched, from being transmitted to the light-emitting element LED and the pixel circuit PC.

The upper elastomer layer 300 may include an elastic polymer. The upper elastomer layer 300 may include thermoplastic polyurethane, silicone, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, and/or polydimethylsiloxane (PDMS). In one or more embodiments, the upper elastomer layer 300 may include the same material as the lower elastomer layer 100a. However, the present disclosure is not limited thereto, and the upper elastomer layer 300 may include a different material from the lower elastomer layer 100a.

FIGS. 7A-7C are each an equivalent circuit diagram of a pixel of a display panel according to one or more embodiments.

Referring to FIG. 7A, the light-emitting element LED corresponding to a pixel may be electrically connected to the pixel circuit PC, and the pixel circuit PC may include a first transistor T1, a second transistor T2, and a storage capacitor Cst. The pixel circuit PC may be electrically connected to a signal line and a voltage line. The signal line may include the gate line GL (FIG. 4), such as a scan signal line GWL, and the data line DL, and the voltage line may include a first voltage line VDDL and a second voltage line VSSL. At this time, the first voltage line VDDL may be connected to the driving voltage supply line W11 (FIG. 4), and the second voltage line VSSL may be connected to a common voltage supply line W13 (FIG. 4).

The second transistor T2 may be electrically connected to the scan signal line GWL and the data line DL. The scan signal line GWL may be configured to provide a scan signal GW to a gate electrode of the second transistor T2. The second transistor T2 may be configured to transmit, to the first transistor T1, a data signal Dm input from the data line DL according to the scan signal GW input from the scan signal line GWL.

The storage capacitor Cst may be electrically connected to the second transistor T2 and the first voltage line VDDL, and may store a voltage corresponding to a difference between a voltage received from the second transistor T2 and the first power voltage VDD supplied by the first voltage line VDDL.

As a driving transistor, the first transistor T1 may be configured to control a driving current flowing through the light-emitting element LED. The first transistor T1 may be connected to the first voltage line VDDL and the storage capacitor Cst. The first transistor T1 may be configured to control a driving current flowing from the first voltage line VDDL to the light-emitting element LED according to a voltage value stored in the storage capacitor Cst. The light-emitting element LED may emit light having a certain luminance according to the driving current. A first electrode of the light-emitting element LED may be electrically connected to the first transistor T1, and a second electrode of the light-emitting element LED may be electrically connected to the second voltage line VSSL configured to supply the second power voltage VSS.

FIG. 7A shows that the pixel circuit PC includes two transistors and one storage capacitor, and in another embodiment, the pixel circuit PC may include at least three transistors.

Referring to FIG. 7B, the pixel circuit PC may include the first transistor T1, the second transistor T2, a third transistor T3, a fourth transistor T4, a fifth transistor T5, a sixth transistor T6, a seventh transistor T7, and the storage capacitor Cst.

The pixel circuit PC may be electrically connected to signal lines and voltage lines. The signal lines may include the gate line GL (FIG. 4), such as the scan signal line GWL, a bypass control line GBL, an initialization control line GIL, and an emission control line EML, and the data line DL. The voltage lines may include first and second initialization voltage lines VIL1 and VIL2 and the first voltage line VDDL. At this time, the first voltage line VDDL may be connected to the driving voltage supply line W11 (FIG. 4), and the second voltage line VSSL may be connected to the common voltage supply line W13 (FIG. 4).

The first voltage line VDDL may be configured to transmit the first power voltage VDD to the first transistor T1. The first initialization voltage line VIL1 may be configured to transmit, to the pixel circuit PC, a first initialization voltage Vint that initializes the first transistor T1. The second initialization voltage line VIL2 may be configured to transmit, to the pixel circuit PC, a second initialization voltage Vaint that initializes the first electrode of the light-emitting element LED.

The first transistor T1 may be electrically connected to the first voltage line VDDL via the fifth transistor T5 and may be electrically connected to the light-emitting element LED via the sixth transistor T6. The first transistor T1 acts as a driving transistor and is configured to receive the data signal Dm according to a switching operation of the second transistor T2 and supply a driving current to the light-emitting element LED.

As a data write transistor, the second transistor T2 is electrically connected to the scan signal line GWL and the data line DL. The second transistor T2 is electrically connected to the first voltage line VDDL via the fifth transistor T5. The second transistor T2 is turned on according to the scan signal GW received through the scan signal line GWL, to perform a switching operation of transmitting, to a first node N1 connected to a first electrode of the first transistor T1, the data signal Dm transmitted to the data line DL.

The third transistor T3 is electrically connected to the scan signal line GWL and is electrically connected to the light-emitting element LED via the sixth transistor T6. The third transistor T3 is also connected between the second electrode and the gate electrode of the first transistor T1. The third transistor T3 may be turned on according to the scan signal GW received through the scan signal line GWL, to diode-connect the first transistor T1.

As a first initialization transistor, the fourth transistor T4 is electrically connected to the initialization control line GIL, the gate electrode of the first transistor T1, and the first initialization voltage line VIL1. The fourth transistor T4 may be turned on according to an initialization control signal GI received through the initialization control line GIL, to transmit the first initialization voltage Vint from the first initialization voltage line VIL1 to a gate electrode of the first transistor T1 and initialize a voltage of the gate electrode of the first transistor T1. The initialization control signal GI may correspond to a scan signal of another pixel circuit arranged in a previous row of the corresponding pixel circuit PC.

The fifth transistor T5 may be an operation control transistor, and the sixth transistor T6 may be an emission control transistor. The fifth transistor T5 and the sixth transistor T6 are electrically connected to the emission control line EML, and are concurrently (e.g., simultaneously) turned on according to an emission control signal EM received through the emission control line EML, to form a current path such that a driving current flows from the first voltage line VDDL to the light-emitting element LED.

As a second initialization transistor, the seventh transistor T7 may be electrically connected to the bypass control line GBL, the second initialization voltage line VIL2, and the sixth transistor T6. The seventh transistor T7 may be turned on according to a bypass control signal GB received through the bypass control line GBL, and may be configured to transmit the second initialization voltage Vaint from the second initialization voltage line VIL2 to the first electrode of the light-emitting element LED and initialize the first electrode of the light-emitting element LED.

The storage capacitor Cst includes a first electrode CE1 and a second electrode CE2. The first electrode CE1 is electrically connected to the gate electrode of the first transistor T1, and the second electrode CE2 is electrically connected to the first voltage line VDDL. The storage capacitor Cst may maintain a voltage applied to the gate electrode of the first transistor T1 by storing and maintaining a voltage corresponding to a difference between voltages at both ends of the gate electrode of the first transistor T1 and the first voltage line VDDL.

Referring to FIG. 7C, the pixel circuit PC may include the first transistor T1, the second transistor T2, the third transistor T3, the fourth transistor T4, the fifth transistor T5, the sixth transistor T6, the seventh transistor T7, an eighth transistor T8, a ninth transistor T9, the storage capacitor Cst, and an auxiliary capacitor Ca.

The pixel circuit PC may be electrically connected to signal lines and voltage lines. The signal lines may include a gate line, such as the scan signal line GWL, the bypass control line GBL, the initialization control line GIL, and the emission control line EML, and the data line DL. The voltage lines may include the first and second initialization voltage lines VIL1 and VIL2, a maintenance voltage line VSL, the first voltage line VDDL, and the second voltage line VSSL. At this time, the first voltage line VDDL may be connected to the driving voltage supply line W11 (FIG. 4), and the second voltage line VSSL may be connected to the common voltage supply line W13 (FIG. 4).

The first voltage line VDDL may be configured to transmit the first power voltage VDD to the first transistor T1. The first initialization voltage line VIL1 may be configured to transmit, to the pixel circuit PC, the first initialization voltage Vint that initializes the first transistor T1. The second initialization voltage line VIL2 may be configured to transmit, to the pixel circuit PC, the second initialization voltage Vaint that initializes the first electrode of the light-emitting element LED. The maintenance voltage line VSL may be configured to provide a maintenance voltage VSUS to a second node N2, for example, the second electrode CE2 of the storage capacitor Cst, during an initialization period and a data write period.

The first transistor T1 may be electrically connected to the first voltage line VDDL via the fifth transistor T5 and the eighth transistor T8, and may be electrically connected to the light-emitting element LED via the sixth transistor T6. The first transistor T1 acts as a driving transistor and may be configured to receive the data signal Dm according to a switching operation of the second transistor T2 and supply a driving current to the light-emitting element LED.

The second transistor T2 is electrically connected to the scan signal line GWL and the data line DL and is electrically connected to the first voltage line VDDL via the fifth transistor T5 and the eighth transistor T8. The second transistor T2 is turned on according to the scan signal GW received through the scan signal line GWL, to perform a switching operation of transmitting, to the first node N1 connected to a first electrode of the first transistor T1, the data signal Dm transmitted to the data line DL.

The third transistor T3 is electrically connected to the scan signal line GWL and is electrically connected to the light-emitting element LED via the sixth transistor T6. The third transistor T3 is also connected between the second electrode and the gate electrode of the first transistor. The third transistor T3 may be turned on according to the scan signal GW received through the scan signal line GWL, to diode-connect the first transistor T1, thereby compensating for a threshold voltage of the first transistor T1.

The fourth transistor T4 is electrically connected to the initialization control line GIL and the first initialization voltage line VIL1, and is turned on according to the initialization control signal GI received through the initialization control line GIL, to transmit the first initialization voltage Vint from the first initialization voltage line VIL1 to the gate electrode of the first transistor T1 and initialize a voltage of the gate electrode of the first transistor T1. The initialization control signal GI may correspond to a scan signal of another pixel circuit arranged in a previous row of the corresponding pixel circuit PC.

The fifth transistor T5, the sixth transistor T6, and the eighth transistor T8 are electrically connected to the emission control line EML, and are concurrently (e.g., simultaneously) turned on according to the emission control signal EM received through the emission control line EML, to form a current path such that a driving current flows from the first voltage line VDDL to the light-emitting element LED.

As a second initialization transistor, the seventh transistor T7 may be electrically connected to the bypass control line GBL, the second initialization voltage line VIL2, and the sixth transistor T6. The seventh transistor T7 is turned on according to the bypass control signal GB received through the bypass control line GBL, to transmit the second initialization voltage Vaint from the second initialization voltage line VIL2 to the first electrode of the light-emitting element LED and initialize the first electrode of the light-emitting element LED.

The ninth transistor T9 may be electrically connected to the bypass control line GBL, the second electrode CE2 of the storage capacitor Cst, and the maintenance voltage line VSL. The ninth transistor T9 may be turned on according to the bypass control signal GB received through the bypass control line GBL, and may be configured to transmit the maintenance voltage VSUS to the second node N2, for example, the second electrode CE2 of the storage capacitor Cst, during an initialization period and a data write period.

Each of the eighth transistor T8 and the ninth transistor T9 may be electrically connected to the second node N2, for example, the second electrode CE2 of the storage capacitor Cst. In one or more embodiments, during an initialization period and a data write period, the eighth transistor T8 may be turned off and the ninth transistor T9 may be turned on, and during an emission period, the eighth transistor T8 may be turned on and the ninth transistor T9 may be turned off. During an initialization period and a data write period, the second node N2 receives the maintenance voltage VSUS, which may improve luminance uniformity (for example, long-range uniformity (LRU)) of a display apparatus according to a drop voltage of the first voltage line VDDL.

The storage capacitor Cst includes the first electrode CE1 and the second electrode CE2. The first electrode CE1 is electrically connected to the gate electrode of the first transistor T1, and the second electrode CE2 is electrically connected to the eighth transistor T8 and the ninth transistor T9.

The auxiliary capacitor Ca may be electrically connected to the sixth transistor T6, the maintenance voltage line VSL, and the first electrode of the light-emitting element LED. While the seventh transistor T7 and the ninth transistor T9 are turned on, the auxiliary capacitor Ca may be configured to store and maintain a voltage corresponding to a difference between voltages of the first electrode of the light-emitting element LED and the maintenance voltage line VSL, thereby preventing an increase in black luminance when the sixth transistor T6 is turned off.

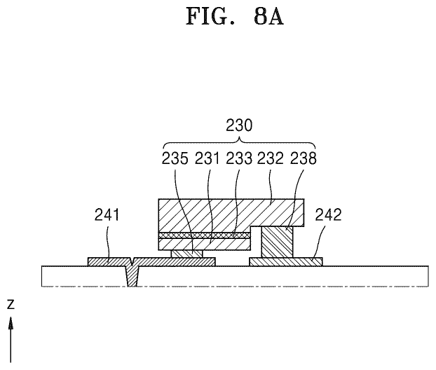

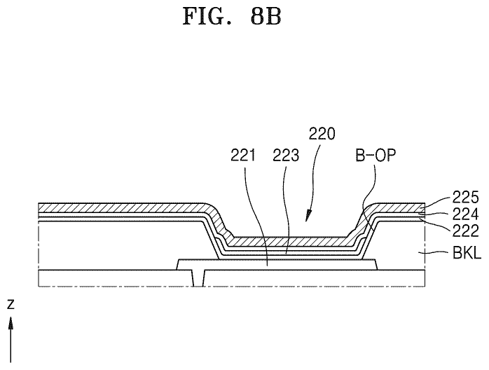

FIGS. 8A and 8B are each a cross-sectional view schematically showing a light-emitting element of a display panel according to one or more embodiments.

Referring to FIG. 8A, the light-emitting element according to one or more embodiments may include an inorganic light-emitting diode 230 including an inorganic material. The inorganic light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the inorganic light-emitting diode 230 may be electrically connected to a first electrode pad 241 and a second electrode pad 242, which are arranged on (or at) the same layer, respectively.

In one or more embodiments, the first semiconductor layer 231 may include a p-type semiconductor layer. The p-type semiconductor layer may be selected from semiconductor materials having a compositional formula InxAlyGa1-x-yN (0≤x≤1, 0≤y≤1, 0≤x+y≤1), such as GaN, AlN, AlGaN, InGaN, InN, InAlGaN, AlInN, etc., and may be doped with a p-type dopant such as Mg, Zn, Ca, Sr, Ba, etc.

The second semiconductor layer 232 may include, for example, an n-type semiconductor layer. The n-type semiconductor layer may be selected from semiconductor materials having a compositional formula InxAlyGa1-x-yN (0≤x≤1, 0≤y≤1, 0≤x+y≤1), such as GaN, AlN, AlGaN, InGaN, InN, InAlGaN, AlInN, etc., and may be doped with a n-type dopant such as Si, Ge, Sn, etc.

The intermediate layer 233 is a region where electrons and holes recombine, and as electrons and holes recombine, the intermediate layer 233 may transition to a lower energy level and may generate light having a corresponding wavelength. The intermediate layer 233 may be formed by including a semiconductor material having, for example, a compositional formula InxAlyGa1-x-yN (0≤x≤1, 0≤y≤1, 0≤x+y≤1), and may be formed to have a single quantum well structure or a multi quantum well (MQW) structure. In addition, the intermediate layer 233 may include a quantum wire structure or a quantum dot structure.

FIG. 8A shows that the first semiconductor layer 231 includes a p-type semiconductor layer and the second semiconductor layer 232 includes an n-type semiconductor layer, but the present disclosure is not limited thereto. In another embodiment, the first semiconductor layer 231 may include an n-type semiconductor layer, and the second semiconductor layer 232 may include a p-type semiconductor layer.

Referring to FIG. 8B, the light-emitting element according to one or more embodiments may include an organic light-emitting diode 220 including an organic material. The organic light-emitting diode 220 may include a first electrode 221 arranged on an insulating layer, a second electrode 225 facing the first electrode 221, and an emission layer 223 arranged between the first electrode 221 and the second electrode 225. A first functional layer 222 may be arranged between the first electrode 221 and the emission layer 223, and a second functional layer 224 may be arranged between the emission layer 223 and the second electrode 225.

An edge of the first electrode 221 may be covered with a bank layer BKL including an insulating material. The bank layer BKL may include an opening B-OP overlapping a central portion of the first electrode 221.

The first electrode 221 may include a conductive oxide, such as indium tin oxide (ITO), indium zinc oxide (IZO), zinc oxide (ZnO), indium oxide (In₂O₃), indium gallium oxide (IGO), and/or aluminum zinc oxide (AZO). In another embodiment, the first electrode 221 may include a reflective layer including silver (Ag), magnesium (Mg), aluminum (AI), platinum (Pt), palladium (Pd), gold (Au), nickel (Ni), neodymium (Nd), iridium (Ir), chromium (Cr), and/or compounds thereof. In another embodiment, the first electrode 221 may further include a layer including ITO, IZO, ZnO, AZO, or In₂O₃ above/under the above-described reflective layer.

The emission layer 223 may include a polymer or low-molecular-weight organic material that emits light of a certain color. The first functional layer 222 may include a hole transport layer (HTL) and/or a hole injection layer (HIL). The second functional layer 224 may include an electron transport layer (ETL) and/or an electron injection layer (EIL).

The second electrode 225 may include a conductive material having a low work function. For example, the second electrode 225 may include a (semi) transparent layer including silver (Ag), magnesium (Mg), aluminum (AI), platinum (Pt), palladium (Pd), gold (Au), nickel (Ni), neodymium (Nd), iridium (Ir), chromium (Cr), lithium (Li), calcium (Ca), and/or alloys thereof. Alternatively, the second electrode 225 may further include a layer including ITO, IZO, ZnO, AZO, and/or In₂O₃ on the (semi) transparent layer including the above-described material.

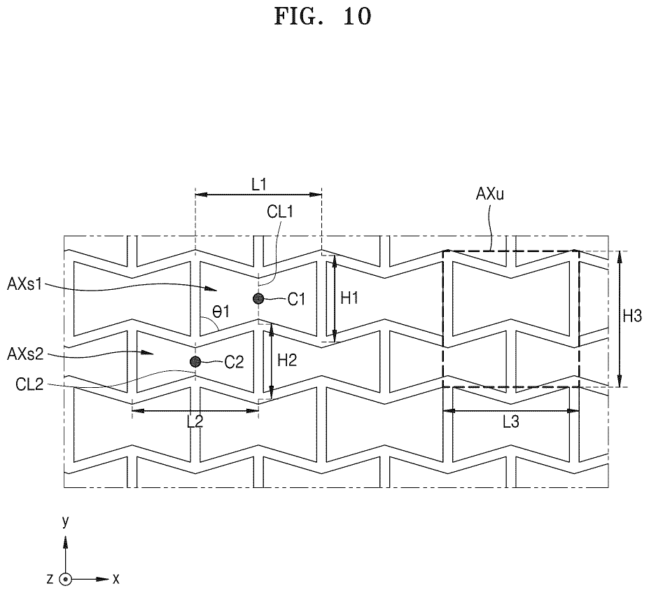

FIG. 9 is a plan view schematically showing a stretch control layer of a display panel according to one or more embodiments. FIG. 10 is an enlarged plan view schematically showing a portion of a stretch control layer of a display panel according to one or more embodiments.

First, referring to FIG. 9, the stretch control layer 100b may include the auxetic structure AX. As described above, because the auxetic structure AX has a negative Poisson's ratio, when the auxetic structure AX is stretched by applying a tensile force in the first direction (for example, x direction), the auxetic structure AX may expand in the second direction (for example, y direction) perpendicular to the first direction (for example, x direction). Accordingly, when the display panel 10 (FIG. 1) is stretched in the first direction (for example, x direction), the stretch control layer 100b including the auxetic structure AX may serve to control the display panel 10 to prevent it from contracting in the second direction (for example, y direction).

The auxetic structure AX may include a plurality of unit structures. In detail, the auxetic structure AX may include a first sub-unit structure AXs1 and a second sub-unit structure AXs2. The auxetic structure AX may be formed such that the first sub-unit structure AXs1 and the second sub-unit structure AXs2 are repeatedly arranged.

In one or more embodiments, each of the first sub-unit structure AXs1 and the second sub-unit structure AXs2 may have a concave polygonal shape. In detail, each of the first sub-unit structure AXs1 and the second sub-unit structure AXs2 may have a concave hexagonal shape. Each of the first sub-unit structure AXs1 and the second sub-unit structure AXs2 may have two interior angles that may be re-entrant angles. In this regard, a re-entrant angle refers to an angle that is greater than 180° and less than 360°. In other words, each of the first sub-unit structure AXs1 and the second sub-unit structure AXs2 may have a ribbon shape or a bow tie shape.

In other words, each of the first sub-unit structure AXs1 and the second sub-unit structure AXs2 may have a re-entrant shape. The auxetic structure AX formed by the repeated arrangement of the first sub-unit structure AXs1 and the second sub-unit structure AXs2 may have a re-entrant hexagonal honeycomb structure.

Referring to FIGS. 9 and 10, the first sub-unit structure AXs1 and the second sub-unit structure AXs2 may have different sizes from each other. In detail, the planar area of the first sub-unit structure AXs1 may be greater than the planar area of the second sub-unit structure AXs2. The first sub-unit structure AXs1 may have a first horizontal length L1 in the first direction (for example, x direction) and a first vertical length H1 in the second direction (for example, y direction). The second sub-unit structure AXs2 may have a second horizontal length L2 in the first direction (for example, x direction) and a second vertical length H2 in the second direction (for example, y direction). At this time, the first horizontal length L1 of the first sub-unit structure AXs1 and the second horizontal length L2 of the second sub-unit structure AXs2 may be equal to each other, and the first vertical length H1 of the first sub-unit structure AXs1 may be greater than the second vertical length H2 of the second sub-unit structure AXs2.

In one or more embodiments, the first sub-unit structure AXs1 may be repeatedly arranged in a first row N1 along the first direction (for example, x direction), and the second sub-unit structure AXs2 may be repeatedly arranged in a second row N2 along the first direction (for example, x direction). The auxetic structure AX may have the first row N1 and the second row N2, which may be repeatedly arranged along the second direction (for example, y direction). In other words, a plurality of first sub-unit structures AXs1 may be arranged in an odd-numbered row of the auxetic structure AX, and a plurality of second sub-unit structures AXs2 may be arranged in an even-numbered row of the auxetic structure AX.

In one or more embodiments, because each of the first sub-unit structure AXs1 and the second sub-unit structure AXs2 has a re-entrant shape, the first sub-unit structure AXs1 and the second sub-unit structure AXs2 may be arranged in different rows from each other and may be alternately arranged relative to each other. For example, with respect to the first direction (for example, x direction), a center C2 of the second sub-unit structure AXs2 may be aligned with a boundary pattern BP arranged between adjacent first sub-unit structures AXs1. In other words, a center C1 of each of the plurality of first sub-unit structures AXs1 may be arranged in a first column M1 along the second direction (for example, y direction), and the center C2 of each of the plurality of second sub-unit structures AXs2 may be arranged in a second column M2 along the second direction (for example, y direction). The auxetic structure AX may have the first column M1 and the second column M2, which may be repeatedly arranged along the first direction (for example, x direction). In other words, the center C1 of the first sub-unit structure AXs1 may be arranged in an odd-numbered column of the auxetic structure AX, and the center C2 of the second sub-unit structure AXs2 may be arranged in an even-numbered column of the auxetic structure AX.

As described above, each of the first sub-unit structure AXs1 and the second sub-unit structure AXs2 may have a re-entrant shape. In other words, each of the first sub-unit structure AXs1 and the second sub-unit structure AXs2 may have a shape formed by an isosceles trapezoid and an inverted isosceles trapezoid meeting each other at a single edge. In other words, the first sub-unit structure AXs1 may have a first-1 divided region AXs11 and a first-2 divided region AXs12 that are symmetrical to each other about an imaginary central line CL1 arranged in the second direction (for example, y direction). The second sub-unit structure AXs2 may have a second-1 divided region AXs21 and a second-2 divided region AXs22 that are symmetrical to each other about an imaginary central line CL2 arranged in the second direction (for example, y direction).

In one or more embodiments, the auxetic structure AX may be formed such that a unit structure AXu is repeatedly arranged along the first direction (for example, x direction) and/or the second direction (for example, y direction). In this regard, the unit structure AXu may be a region formed by combining the first sub-unit structure AXs1 and the second sub-unit structure AXs2. For example, the unit structure AXu may include one first sub-unit structure AXs1 arranged in an i^{th} row and a j^{th} column, a second divided region AXs22 of the second sub-unit structure AXs2 arranged in an (i+1)^{th} row and a (j−1)^{th} column, and a first divided region AXs21 of the second sub-unit structure AXs2 arranged in the (i+1)^{th} row and a (j+1)^{th} column. In other words, the unit structure AXu may include one first sub-unit structure AXs1, the second divided region AXs22 of one second sub-unit structure AXs2 arranged adjacent to the first sub-unit structure AXs1, and the first divided region AXs21 of another second sub-unit structure AXs2.

The unit structure AXu may have a third horizontal length L3 in the first direction (for example, x direction) and a third vertical length H3 in the second direction (for example, y direction). The third horizontal length L3 of the unit structure AXu may be equal to the first horizontal length L1 of the first sub-unit structure AXs1. The third vertical length H3 of the unit structure AXu may be equal to the sum of the first vertical length H1 of the first sub-unit structure AXs1 and the length of the imaginary central line CL2 of the second sub-unit structure AXs2.

In one or more embodiments, the third horizontal length L3 and the third vertical length H3 may be in a ratio of 1:1. This is to ensure that when the auxetic structure AX is subjected to a tensile force in the first direction (for example, x direction) and stretched by a certain length, the auxetic structure AX may also be stretched by a similar length in the second direction (for example, y direction). In addition, this is to ensure that when the display panel is stretched in the first direction (for example, x direction) and the second direction (for example, y direction), a difference in resistance between a connection wire extending in the first direction (for example, x direction) and a connection wire extending in the second direction (for example, y direction) is reduced or minimized.

However, the present disclosure is not limited thereto, and the third horizontal length L3 and the third vertical length H3 may not be in a ratio of 1:1. In another embodiment, when the third horizontal length L3 is greater than the third vertical length H3, the third horizontal length L3 may be an integer multiple of the third vertical length H3. In another embodiment, when the third vertical length H3 is greater than the third horizontal length L3, the third vertical length H3 may be an integer multiple of the third horizontal length L3. The ratio of the third horizontal length L3 and the third vertical length H3 may be freely adjusted to ensure that spacing between light-emitting elements LED in the first direction (for example, x direction) and spacing between light-emitting elements LED in the second direction (for example, y direction) are the same.

In one or more embodiments, the auxetic structure AX may include a plurality of openings OP and the boundary pattern BP forming a boundary between the plurality of openings OP. The plurality of openings OP may be separated from each other by being partitioned by the boundary pattern BP. For example, the first sub-unit structure AXs1 may include a boundary pattern BP forming a re-entrant shape and a first opening OP1 defined by the corresponding boundary pattern BP. The second sub-unit structure AXs2 may include a boundary pattern BP forming a re-entrant shape and a second opening OP2 defined by the corresponding boundary pattern BP. In other words, the first sub-unit structure AXs1 may have a closed line shape including the first opening OP1, and the second sub-unit structure AXs2 may have a closed line shape including the second opening OP2. In one or more embodiments, the planar area of the first opening OP1 may be greater than the planar area of the second opening OP2.

The first opening OP1 and the second opening OP2 may be occupied by the lower elastomer layer 100a (FIG. 6A). An elastomer occupying the first opening OP1 and the second opening OP2 may absorb stress that may be concentrated on the boundary pattern BP, thereby distributing stress applied to the auxetic structure AX.

The boundary pattern BP forming the re-entrant shape of the first sub-unit structure AXs1 may include first to sixth boundary patterns BP1, BP2, BP3, BP4, BP5, and BP6. In other words, the first to sixth boundary patterns BP1, BP2, BP3, BP4, BP5, and BP6 may be integrally connected to each other to form the concave hexagonal shape of the first sub-unit structure AXs1. For example, the first boundary pattern BP1 and the fourth boundary pattern BP4 may extend in the second direction (for example, y direction) and may be parallel to each other, the second boundary pattern BP2 and the sixth boundary pattern BP6 may extend in a third direction (for example, a DR3 direction) and may be parallel to each other, and the third boundary pattern BP3 and the fifth boundary pattern BP5 may extend in a fourth direction (for example, a DR4 direction) and may be parallel to each other.

The first boundary pattern BP1 and the second boundary pattern BP2 may be integrally connected to each other and form an acute angle, the second boundary pattern BP2 and the third boundary pattern BP3 may be integrally connected to each other and form a re-entrant angle, and the third boundary pattern BP3 and the fourth boundary pattern BP4 may be integrally connected to each other and form an acute angle. Likewise, the fourth boundary pattern BP4 and the sixth boundary pattern BP6 may be integrally connected to each other and form an acute angle, the sixth boundary pattern BP6 and the fifth boundary pattern BP5 may be integrally connected to each other and form a re-entrant angle, and the fifth boundary pattern BP5 and the first boundary pattern BP1 may be integrally connected to each other and form an acute angle. The second sub-unit structure AXs2 may also have a boundary pattern having a structure similar to that of the first sub-unit structure AXs1.

When the auxetic structure AX is subjected to a tensile force in the first direction (for example, x direction) and stretched in the first direction, a distance between the first boundary pattern BP1 and the fourth boundary pattern BP4 may increase. At this time, as the distance between the first boundary pattern BP1 and the fourth boundary pattern BP4 increases, the second, third, fifth, and sixth boundary patterns BP2, BP3, BP5, and BP6, which are integrally connected to the first boundary pattern BP1 and the fourth boundary pattern BP4, may also move away from the center C1. For example, when the auxetic structure AX is subjected to a tensile force in the first direction (for example, x direction), an angle θ1 formed by the first boundary pattern BP1 and the fifth boundary pattern BP5 may gradually increase. In other words, as the angle θ1 formed by the first boundary pattern BP1 and the fifth boundary pattern BP5 increases, a distance between the second boundary pattern BP2 and the fifth boundary pattern BP5 may also increase. As a result, when the auxetic structure AX is stretched in the first direction (for example, x direction), the auxetic structure AX may also be stretched in the second direction (for example, y direction). In other words, the auxetic structure may have a negative Poisson's ratio.

The boundary pattern BP of the auxetic structure AX may control (e.g., may be required to control) the stretching of the display panel 10 and thus may have a large modulus. In one or more embodiments, the auxetic structure AX may have a modulus of at least 3 GPa. For example, the modulus of the auxetic structure AX may be 150 times or more than the modulus of a substrate used in a process of forming the display panel 10. Because the boundary pattern BP includes a material with high rigidity, the display layer 200 (FIG. 6A) arranged above the stretch control layer 100b may be prevented from contracting in the second direction (for example, y direction), by applying a force in the opposite direction. For example, boundary pattern BP may include polydimethylsiloxane (PDMS) and/or polyurethane (PU). In one or more embodiments, the modulus of the boundary pattern BP may be increased by adjusting the mixing proportion of a cross-linker included in the boundary pattern BP.

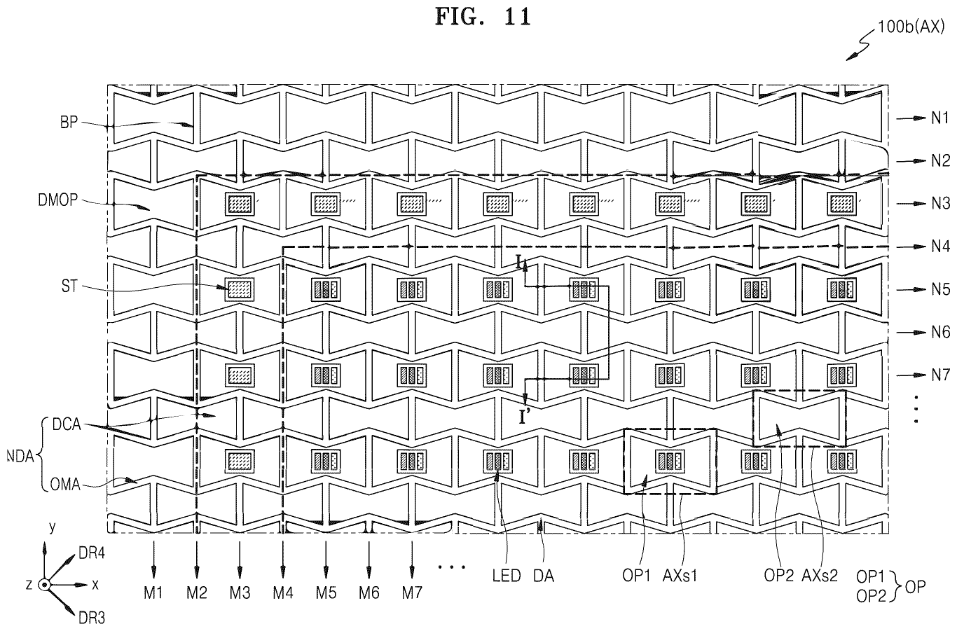

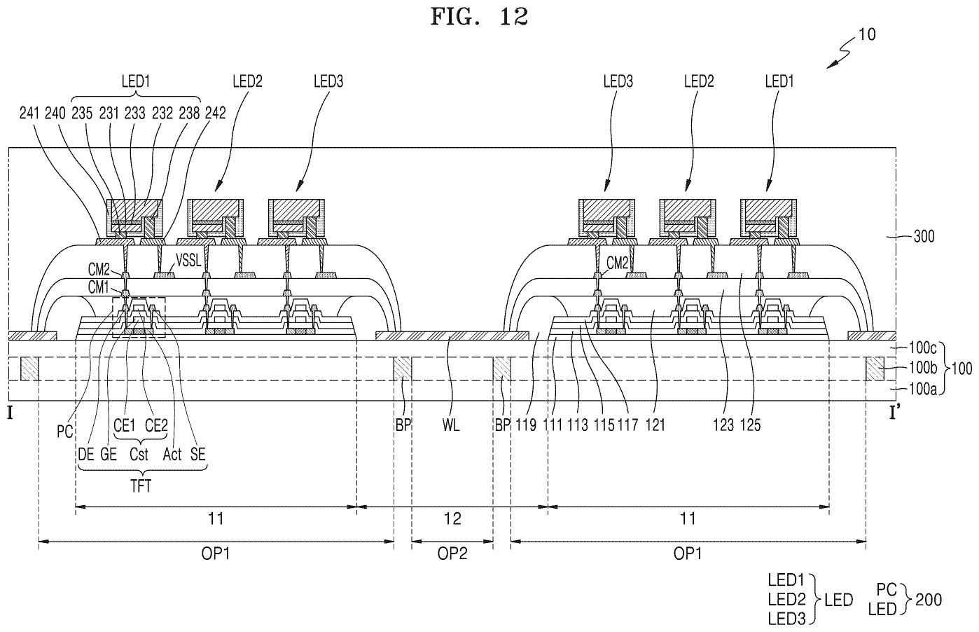

FIG. 11 is a plan view schematically showing a display panel according to one or more embodiments. FIG. 12 is a cross-sectional view schematically showing a display panel according to one or more embodiments. In detail, FIG. 12 may be a cross-section of the display panel of FIG. 11 taken along the line I-I′ of FIG. 11.

Referring to FIG. 11, the display panel 10 (FIG. 1) may include the display area DA and the non-display area NDA. At this time, the stretch control layer 100b may include the display area DA overlapping the light-emitting element LED of the display layer 200 (FIG. 6A), a driving circuit region DCA overlapping a stage ST of the gate driving circuit GDC (FIG. 4), and an outermost region OMA, which is outside the gate driving circuit GDC (FIG. 4). The driving circuit region DCA and the outermost region OMA may be the non-display area NDA.

In one or more embodiments, the light-emitting element LED may be arranged to overlap each of the plurality of openings OP in the auxetic structure AX. In detail, the light-emitting element LED may be arranged to overlap the first opening OP1 in the first sub-unit structure AXs1, and the light-emitting element LED may not overlap the second opening OP2 in the second sub-unit structure AXs2. In other words, the light-emitting element LED may be arranged in an odd-numbered row and column where the first sub-unit structure AXs1 is arranged. This is to ensure that the light-emitting elements LED are not arranged in a zigzag shape by allowing the light-emitting elements LED to be arranged in specific rows and columns where the first sub-unit structures AXs1 are arranged. Because the light-emitting elements LED are arranged in lines, even when the display panel 10 (FIG. 1) is stretched, the arrangement of the light-emitting elements LED may be stably maintained.

In one or more embodiments, the light-emitting element LED may be arranged to overlap the center C1 (FIG. 9) of the first sub-unit structure AXs1. As described above, when the display panel 10 (FIG. 1) is stretched, stress may be concentrated on the boundary pattern BP of the auxetic structure AX, and an elastomer arranged in an opening OP may absorb the stress. In detail, stress may be concentrated on the boundary pattern BP of the auxetic structure AX, which extends in a direction in which the display panel 10 (FIG. 1) is stretched. Accordingly, strain may be smallest at the center C1 (FIG. 9) of the first opening OP1 in the first sub-unit structure AXs1. In a case where the light-emitting element LED is arranged to overlap the center C1 (FIG. 9), even when the display panel 10 (FIG. 1) is stretched, the light-emitting element LED may be stably driven.

Referring to FIG. 12, the display layer 200 may be arranged on the support layer 100, and the upper elastomer layer 300 may be arranged on the display layer 200. In one or more embodiments, the support layer 100 may have a structure in which the lower elastomer layer 100a, the stretch control layer 100b, and the auxiliary elastomer layer 100c are sequentially stacked. In another embodiment, as described with reference to FIG. 6B, the support layer 100 may include only the lower elastomer layer 100a and the stretch control layer 100b. The stretch control layer 100b may have a structure in which the boundary pattern BP of the auxetic structure AX (FIG. 11) is embedded in the lower elastomer layer 100a and the auxiliary elastomer layer 100c.

The support layer 100 may define the pixel regions 11 and the connection region 12 between the pixel regions 11. The pixel circuit PC and the light-emitting element LED connected to the pixel circuit PC may be arranged in the pixel region 11 of the support layer 100.

A buffer layer 111 may be arranged on the support layer 100, and the pixel circuit PC may be arranged on the buffer layer 111. The buffer layer 111 may include an inorganic insulating material such as silicon oxide, silicon nitride, and/or silicon oxynitride.

A thin-film transistor TFT may include a semiconductor layer Act, a gate electrode GE, a source electrode SE, and a drain electrode DE. FIG. 12 shows that the thin-film transistor TFT is of a top-gate type in which the gate electrode GE is arranged on the semiconductor layer Act with a gate insulating layer 113 therebetween, but according to another embodiment, the thin-film transistor TFT may be of a bottom-gate type.

The semiconductor layer Act may include polysilicon. Alternatively, the semiconductor layer Act may include amorphous silicon, an oxide semiconductor, and/or an organic semiconductor. The gate electrode GE may include a metal thin film including a low-resistance metal material. The gate electrode GE may include a conductive material including molybdenum (Mo), aluminum (AI), copper (Cu), titanium (Ti), etc., and may be formed as a multilayer or a single layer, each including the material. For example, the gate electrode GE may be provided as a metal thin film including three layers of a titanium (Ti)/aluminum (Al)/titanium (Ti) structure.

The gate insulating layer 113 between the semiconductor layer Act and the gate electrode GE may include an inorganic insulating material such as silicon oxide, nitrogen oxide, silicon oxynitride, aluminum oxide, or titanium oxide. The gate insulating layer 113 may be formed as a single layer or a multilayer, each including the above-described material.

The source electrode SE and the drain electrode DE may be arranged on the same layer, for example, a second interlayer insulating layer 117, and may include the same material. Each of the source electrode SE and the drain electrode DE may include a metal thin film including a low-resistance metal material. Each of the source electrode SE and the drain electrode DE may include a conductive material including molybdenum (Mo), aluminum (AI), copper (Cu), titanium (Ti), etc., and may be formed as a multilayer and a single layer, each including the material. For example, like the gate electrode GE, each of the source electrode SE and the drain electrode DE may be provided as a metal thin film including three layers of a titanium (Ti)/aluminum (Al)/titanium (Ti) structure. The second interlayer insulating layer 117 may include an inorganic insulating material such as silicon oxide, nitrogen oxide, silicon oxynitride, aluminum oxide, and/or titanium oxide, and may be formed as a single layer or a multilayer, each including the above-described material.

The storage capacitor Cst may include the first electrode CE1 and the second electrode CE2, which overlap each other with a first interlayer insulating layer 115 therebetween. The storage capacitor Cst may overlap the thin-film transistor TFT. In this regard, FIG. 12 shows that the gate electrode GE of the thin-film transistor TFT is the first electrode CE1 of the storage capacitor Cst. In another embodiment, the storage capacitor Cst may not overlap the thin-film transistor TFT. The storage capacitor Cst may be covered with the second interlayer insulating layer 117.

The first interlayer insulating layer 115 may be arranged between the gate insulating layer 113 and the second interlayer insulating layer 117. The first interlayer insulating layer 115 may include an inorganic insulating material such as silicon oxide, nitrogen oxide, silicon oxynitride, aluminum oxide, and/or titanium oxide, and may be formed as a single layer or a multilayer, each including the above-described material.

The second electrode CE2 of the storage capacitor Cst may include a conductive material and may be formed as a multilayer or a single layer. The second electrode CE2 may include a metal thin film including a low-resistance metal material. The second electrode CE2 may include a conductive material including molybdenum (Mo), aluminum (AI), copper (Cu), titanium (Ti), etc., and may be formed as a multilayer or a single layer, each including the material. For example, the second electrode CE2 may be provided as a metal thin film including three layers of a titanium (Ti)/aluminum (Al)/titanium (Ti) structure.

A first organic insulating layer 121 may be arranged on the second interlayer insulating layer 117, and a second organic insulating layer 123 may be arranged on the first organic insulating layer 121. Each of the first organic insulating layer 121 and the second organic insulating layer 123 may include an organic insulating material such as polyimide.

The sub organic insulating layer 119 may be arranged between the second interlayer insulating layer 117 and the first organic insulating layer 121 in an outer region of the pixel region 11 adjacent to the connection region 12. In one or more embodiments, a wire that connects the connection wire WL to the pixel circuit PC may be arranged on a sub organic insulating layer 119. The sub organic insulating layer 119 may include an organic insulating material such as polyimide.

A first connection electrode CM1 may be arranged on the first organic insulating layer 121, and a second connection electrode CM2 may be arranged on the second organic insulating layer 123. The first connection electrode CM1 and the second connection electrode CM2 may electrically connect the thin-film transistor TFT to the light-emitting element LED. Each of the first connection electrode CM1 and the second connection electrode CM2 may include a metal thin film including a low-resistance metal material. Each of the first connection electrode CM1 and the second connection electrode CM2 may include a conductive material including molybdenum (Mo), aluminum (Al), copper (Cu), titanium (Ti), etc., and may be formed as a multilayer or a single layer, each including the material. For example, each of the first connection electrode CM1 and the second connection electrode CM2 may be provided as a metal thin film including three layers of a titanium (Ti)/aluminum (Al)/titanium (Ti) structure.

The second voltage line VSSL may be arranged on the second organic insulating layer 123, and a third organic insulating layer 125 may be arranged on the second insulating layer 123 and the second voltage line VSSL. The third organic insulating layer 125 may include an organic insulating material such as polyimide. The second voltage line VSSL may be connected to the common voltage supply line W13 (FIG. 4) to transmit the second power voltage VSS (FIG. 7A) to the second electrode 238. The second voltage line VSSL may include a conductive material and may be formed as a multilayer or a single layer.

The first electrode pad 241 and the second electrode pad 242 may be arranged on the third organic insulating layer 125. The first electrode pad 241 may be electrically connected to the thin-film transistor TFT through the first connection electrode CM1 between the first organic insulating layer 121 and the second organic insulating layer 123 and through the second connection electrode CM2 between the second organic insulating layer 123 and the third organic insulating layer 125. The light-emitting element LED on the first electrode pad 241 and the second electrode pad 242 may be the same as the inorganic light-emitting diode 230 described above with reference to FIG. 8A. The light-emitting element LED, which is the inorganic light-emitting diode 230 (FIG. 8A) may include the first semiconductor layer 231, the second semiconductor layer 232, the intermediate layer 233 between the first semiconductor layer 231 and the second semiconductor layer 232, the first electrode 235 electrically connected to the first semiconductor layer 231, and the second electrode 238 electrically connected to the second semiconductor layer 232. The light-emitting element LED may be covered with a protective layer 240. The protective layer 240 may include an organic insulating material such as polyimide.

The connection wire WL may be arranged in the connection region 12 of the support layer 100. The connection wire WL may be a signal line (for example, a gate line, a date line, etc.) for providing an electrical signal to the thin-film transistor TFT of the pixel circuit PC, or a voltage line (for example, a first voltage line, an initialization voltage line, etc.) for providing a voltage to the thin-film transistor TFT of the pixel circuit PC. The connection region 12 may be a region where the most deformation occurs when the display panel 10 is stretched. Accordingly, the connection wire WL may include a material that has both electrical characteristics and suitable elasticity (e.g., excellent elasticity). In one or more embodiments, the connection wire WL may include a metal nanostructure and/or an elastic polymer. In another embodiment, the connection wire WL may include liquid metal. However, the present disclosure is not limited thereto, and the connection wire WL may include a material with a smaller modulus than a conductive layer included in the thin-film transistor TFT.

Because the connection region 12 of the support layer 100 may undergo significant deformation, organic insulating layers may be arranged in the connection region 12. For example, the sub organic insulating layer 119, the first organic insulating layer 121, the second organic insulating layer 123, and the third organic insulating layer 125, which are arranged in the pixel region 11, may extend into the connection region 12.

The upper elastomer layer 300 may be arranged on the light-emitting element LED and the connection wire WL. The upper elastomer layer 300 may cover the light-emitting element LED and the connection wire WL to absorb stress that may be transmitted to the light-emitting element LED and the connection wire WL. In one or more embodiments, the upper elastomer layer 300 may include the same material as the lower elastomer layer 100a. However, the present disclosure is not limited thereto, and in another embodiment, the upper elastomer layer 300 may include a different material from the lower elastomer layer 100a.

As described above, the light-emitting element LED may be arranged to overlap the first opening OP1 in the auxetic structure AX (FIG. 11). In other words, the first opening OP1 may overlap the pixel region 11. The connection region 12 surrounds the pixel region 11 and may be where the connection wire WL is arranged. Accordingly, in one or more embodiments, the second opening OP2 may overlap the connection wire WL. In other words, the second opening OP2 may overlap the connection region 12. However, a portion of the connection region 12 may overlap the second opening OP2, and the remaining portion of the connection region 12 may also overlap the first opening OP1.

Referring to FIG. 11 again, the driving circuit region DCA may be arranged outside the display area DA. The gate driving circuit GDC (FIG. 4) may include a plurality of stages ST. In one or more embodiments, each of the stages ST may be arranged to overlap the first opening OP1 in the first sub-unit structure AXs1. Like the light-emitting element LED, each of the stages ST may be arranged to overlap the center C1 (FIG. 9) of the first opening OP1. This may be to ensure that each stage ST is arranged at a position with the lowest strain.

In one or more embodiments, as shown in FIG. 11, the plurality of stages ST may be arranged to surround the display area DA. However, the present disclosure is not limited thereto, and in another embodiment, the plurality of stages ST may be arranged only at both sides of the display area DA. In other words, the driving circuit region DCA may be arranged only on left and right sides of the display area DA, and the driving circuit region DCA may not be arranged on upper and lower sides of the display area DA.

The outermost region OMA may be arranged outside the driving circuit region DCA. The light-emitting element LED, the stage ST, etc. may not be arranged in the outermost region OMA. In other words, the first opening OP1 in the outermost region OMA may not overlap the light-emitting element LED and the stage ST. The first opening OP1 in the outermost region OMA may be also referred to as a dummy opening DMOP. When the display panel 10 (FIG. 1) is stretched, the outermost region of the stretch control layer 100b may be where stress is most concentrated. Accordingly, the dummy opening DMOP may be arranged in the outermost region of the stretch control layer 100b, thereby reducing or minimizing the impact on the light-emitting element LED, etc.

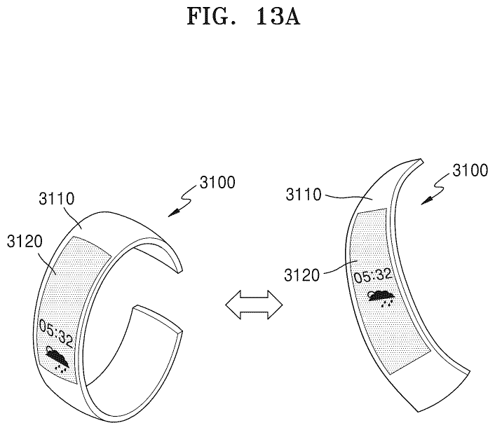

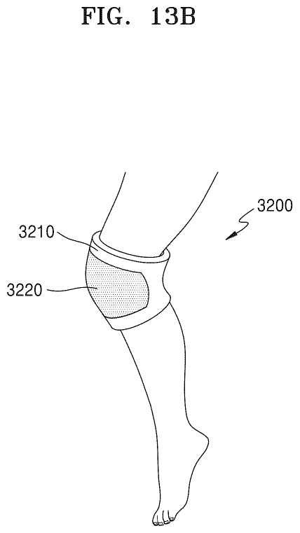

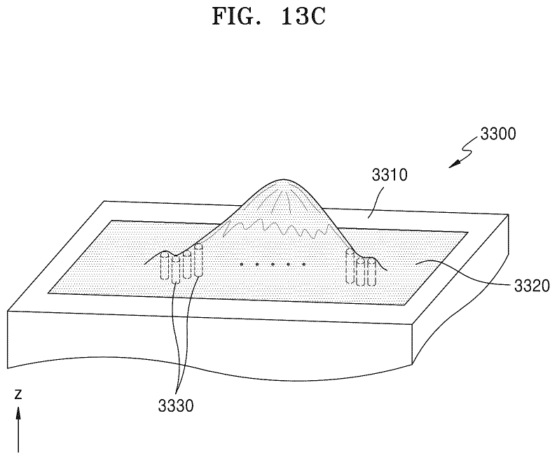

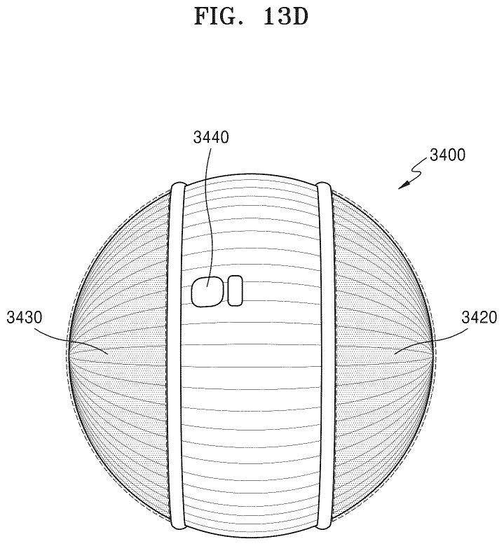

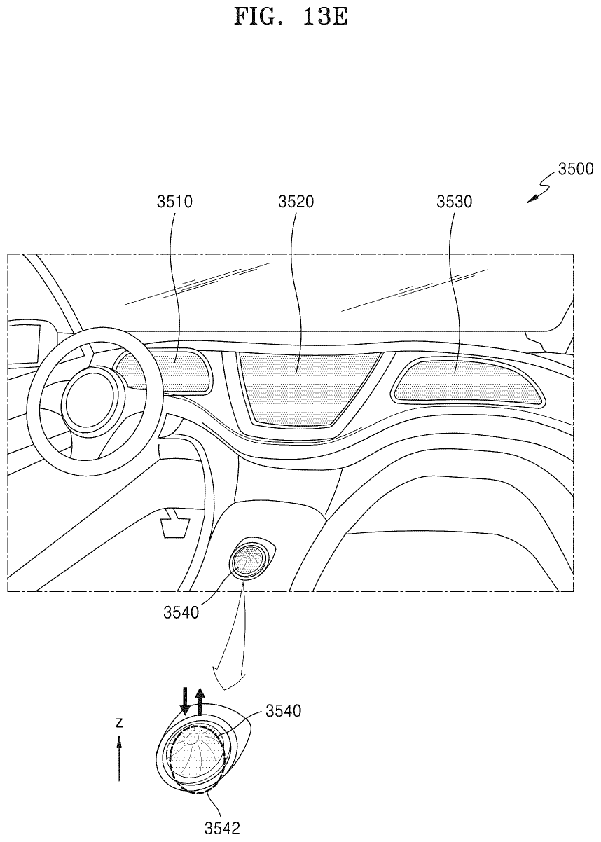

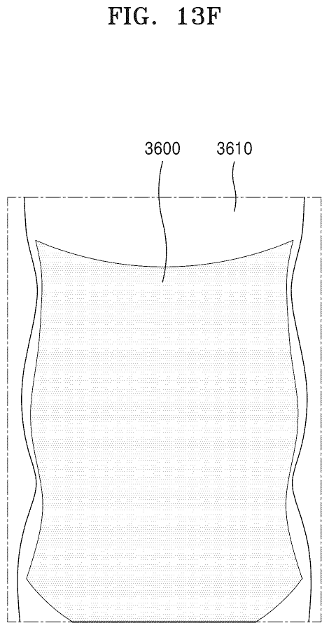

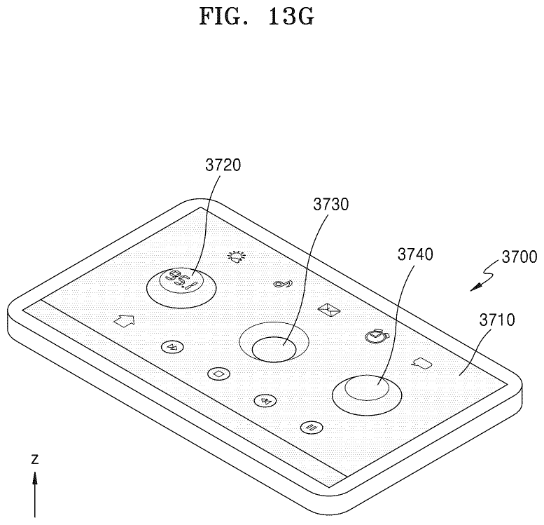

FIGS. 13A-13G are each a perspective view schematically showing embodiments of an electronic device including a display apparatus according to one or more embodiments.

Referring to FIG. 13A, the display apparatus according to one or more embodiments may be utilized in a wearable electronic device 3100 that may be worn on part of a user's body. The wearable electronic device 3100 may include a body part 3110 and a display part 3120 provided on the body part 3110. The display apparatus according to one or more embodiments may be used as the display part 3120 of the wearable electronic device 3100. As shown in FIG. 13A, the wearable electronic device 3100 may be deformable. In one or more embodiments, the wearable electronic device 3100 may be used as a smart watch or a smartphone, depending on a user's choice.

FIG. 13B shows a medical electronic device 3200. In one or more embodiments, the medical electronic device 3200 may include a body part 3210 and a light-emitting part 3220. The display apparatus according to one or more embodiments may be used as the light-emitting part 3220 of the medical electronic device 3200. The light-emitting part 3220 may emit light (for example, infrared light, visible light, etc.) in a certain wavelength band onto a patient's body. In one or more embodiments, the body part 3210 may include a stretchable fiber material, and the light-emitting part 3220 may have a structure that may be worn on a user's body.

FIG. 13C shows an educational electronic device 3300. In one or more embodiments, the educational electronic device 3300 may include a display part 3320 provided in a frame 3310. The display part 3320 may use the display apparatus according to one or more embodiments. An image, such as a sea with waves, a mountain covered in snow, and/or a volcano with flowing lava, may be provided through the display part 3320, and at this time, the display part 3320 may expand in a height direction (for example, z direction) to reflect the height of the waves, mountain, and/or volcano. In one or more embodiments, a portion of the display part 3320 may sequentially vary in height in a direction in which the lava flows, allowing the movement of the lava to be displayed in three dimensions. The educational electronic device 3300 may include a plurality of pins (or stroke parts) 3330 arranged on a rear surface of the display part 3320 to allow the display part 3320 to expand in the height direction. The pins 3330 may allow an image displayed on the display part 3320 to have a three-dimensional height while moving in a third direction (for example, z direction or −z direction). FIG. 13C illustrates the educational electronic device 3300, but its use is not limited as long as the educational electronic device 3300 provides certain image information.

The electronic devices shown in FIGS. 13A-13C may each have a variable shape, but the present disclosure is not limited thereto. As in the following embodiments, the display apparatus according to one or more embodiments may be used in an electronic device in which a portion (for example, a screen) capable of displaying an image is fixed.

FIG. 13D shows a robot 3400 as the electronic device according to one or more embodiments. The robot 3400 may recognize movement or an object by using a camera part 3440, and may display a certain image to a user through display parts 3420 and 3430. In one or more embodiments, the display apparatuses according to one or more embodiments may expand in various directions as described above and thus may be assembled into a hemispherical body frame. Therefore, the robot 3400 may include the hemispherical display parts 3420 and 3430.

FIG. 13E shows a vehicle display device 3500 as the electronic device according to one or more embodiments. The vehicle display device 3500 may include a cluster 3510, a center information display (CID) 3520, and/or a co-driver display 3530. The display apparatus according to one or more embodiments may expand in various directions and thus may be used in the cluster 3510, the CID 3520, and/or the co-driver display 3530, without being constrained by the shape of a vehicle's internal frame.

FIG. 13E shows the cluster 3510, the CID 3520, and/or the co-driver display 3530 as separate components, but the present disclosure is not limited thereto. In another embodiment, at least two selected from the cluster 3510, the CID 3520, and the co-driver display 3530 may be integrally connected to each other as a single body.

In one or more embodiments, the vehicle display device 3500 may include a button 3540 capable of displaying a certain image. Referring to an enlarged view of FIG. 13E, the hemispherical button 3540 may include an object 3542 that provides the sensation of using the button 3540 while moving in the z direction or −z direction, as well as a display apparatus arranged above the object 3542. In one or more embodiments, when the object 3542 has a three-dimensionally rounded surface, the display apparatus may also have a three-dimensionally rounded surface.

FIG. 13F shows that the electronic device according to one or more embodiments is an advertising or exhibition electronic device 3600. In one or more embodiments, the advertising or exhibition electronic device 3600 may be installed on a fixed structure 3610 such as a wall or a pillar. When the structure 3610 includes an uneven surface as shown in FIG. 13F, the advertising or exhibition electronic device 3600 may also be arranged along the uneven surface of the structure 3610. In one or more embodiments, the advertising or exhibition electronic device 3600 may be installed on the structure 3610 by using a heat-shrink film, etc.

FIG. 13G shows that the electronic device according to one or more embodiments is a controller 3700. The controller 3700 may include an image-type button. For example, the controller 3700 may include first to third button regions 3720, 3730, and 3740 where a partial region of a display part 3710 protrudes in the z direction or protrudes-z direction (or is recessed in the z direction). In one or more embodiments, the first and third button regions 3720 and 3740 may protrude in the z direction, and the second button region 3730 may protrude in the −z direction (or may be recessed in the z direction).

According to one or more embodiments, a display panel that implements an image of excellent quality even when stretched, as well as an electronic device, may be provided. The aforementioned effects, aspects, and features are merely examples, and the effects, aspects, and features of the present disclosure are not limited to those described above.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and their equivalents.

What is claimed is:

1. A display panel comprising:
a support layer comprising a lower elastomer layer and a stretch control layer on the lower elastomer layer, the support layer having a display area and a non-display area around the display area in a plan view; and
a display layer comprising a pixel circuit in the display area of the support layer and a light-emitting element electrically connected to the pixel circuit,
wherein the stretch control layer comprises an auxetic structure comprising a first sub-unit structure and a second sub-unit structure having a smaller planar area than the first sub-unit structure,
wherein the first sub-unit structure comprises a plurality of first sub-unit structures, and the plurality of first sub-unit structures are continuously arranged in a first row along a first direction,
wherein the second sub-unit structure comprises a plurality of second sub-unit structures, and the plurality of second sub-unit structures are continuously arranged in a second row along the first direction, and
wherein the first row and the second row are repeatedly arranged along a second direction crossing the first direction.

2. The display panel of claim 1, wherein the auxetic structure has a negative Poisson's ratio.

3. The display panel of claim 1, wherein each of the first sub-unit structure and the second sub-unit structure has a concave polygonal shape.

4. The display panel of claim 1, wherein each of the first sub-unit structure and the second sub-unit structure has a re-entrant shape.

5. The display panel of claim 1, wherein the first sub-unit structure and the second sub-unit structure are alternately arranged relative to each other with respect to the first direction.

6. The display panel of claim 1, wherein the first sub-unit structure has a first horizontal length in the first direction and a first vertical length in the second direction,
wherein the second sub-unit structure has a second horizontal length in the first direction and a second vertical length in the second direction, and
wherein the first vertical length is greater than the second vertical length.

7. The display panel of claim 6, wherein the first horizontal length is equal to the second horizontal length.

8. The display panel of claim 6, wherein the second sub-unit structure comprises a first divided region and a second divided region that are symmetrical to each other with respect to an imaginary central line extending along the second direction and located at a center of the second sub-unit structure.

9. The display panel of claim 8, wherein a sum of the first vertical length and a length of the imaginary central line is equal to the first horizontal length.

10. The display panel of claim 8, wherein the auxetic structure is formed such that a unit structure comprising a combination of the first sub-unit structure and the second sub-unit structure is repeatedly arranged, and
wherein the unit structure comprises:
the first sub-unit structure arranged in an n^{th} row and an m^{th} column;
the second divided region of the second sub-unit structure arranged in an (n+1)^{th} row and an (m−1)^{th} column; and
the first divided region of the second sub-unit structure arranged in the (n+1)^{th} row and an (m+1)^{th} column.

11. The display panel of claim 10, wherein the unit structure has a third horizontal length in the first direction and a third vertical length in the second direction, and
wherein the third horizontal length and the third vertical length are in a ratio of 1:1.

12. The display panel of claim 1, wherein the auxetic structure comprises a plurality of openings and a boundary pattern forming a boundary between the plurality of openings, and
wherein the boundary pattern of the auxetic structure has a modulus of at least 3 GPa.

13. The display panel of claim 12, wherein the lower elastomer layer is in the plurality of openings, and
wherein, in a plan view, the light-emitting element overlaps a center of each of the plurality of openings.

14. The display panel of claim 12, wherein the plurality of openings comprises a first opening and a second opening having different planar areas from each other,
wherein the first sub-unit structure has a closed line shape including the first opening,
wherein the second sub-unit structure has a closed line shape including the second opening, and
wherein, in a plan view, the light-emitting element overlaps the first opening.

15. The display panel of claim 14, wherein the display area includes:
a pixel region where the light-emitting element is arranged; and
a connection region around the pixel region and in which a connection wire is arranged to connect adjacent pixel circuits,
wherein the connection wire is stretchable.

16. The display panel of claim 15, wherein, in a plan view, the pixel region overlaps the first opening, and the connection region overlaps the second opening and a partial region of the first opening, the partial region excluding a region overlapping the pixel region.

17. The display panel of claim 12, further comprising a gate driving circuit in the non-display area of the support layer, configured to transmit a gate signal to the pixel circuit, and comprising a plurality of stages,
wherein the plurality of stages of the gate driving circuit are arranged to overlap the plurality of openings, respectively, and
wherein the plurality of openings includes a dummy opening arranged outside the gate driving circuit.

18. The display panel of claim 1, further comprising an upper elastomer layer on the display layer and covering the light-emitting element,
wherein the support layer further comprises an auxiliary elastomer layer between the stretch control layer and the display layer.

19. An electronic device comprising:
a display panel; and
a lower cover forming an exterior of the display panel and having an opening exposing a portion of the display panel to a front surface of the electronic device,
wherein the display panel comprises:
a support layer comprising a lower elastomer layer and a stretch control layer on the lower elastomer layer, the support layer having a display area and a non-display area around the display area, in a plan view; and
a display layer comprising a pixel circuit in the display area of the support layer and a light-emitting element electrically connected to the pixel circuit,
wherein the stretch control layer comprises an auxetic structure comprising a first sub-unit structure and a second sub-unit structure having a smaller planar area than the first sub-unit structure,
wherein the first sub-unit structure comprises a plurality of first sub-unit structures, and the plurality of first sub-unit structures are continuously arranged in a first row in a first direction,
wherein the second sub-unit structure comprises a plurality of second sub-unit structures, and the plurality of second sub-unit structures are continuously arranged in a second row in the first direction, and
wherein the first row and the second row are repeatedly arranged along a second direction crossing the first direction.

20. The electronic device of claim 19, wherein the second sub-unit structure comprises a first divided region and a second divided region that are symmetrical to each other with respect to an imaginary central line extending along the second direction and located at a center of the second sub-unit structure,
wherein the auxetic structure is formed such that a unit structure comprising a combination of the first sub-unit structure and the second sub-unit structure is repeatedly arranged, and
wherein the unit structure comprises:
the first sub-unit structure arranged in an n^{th} row and an m^{th} column;
the second divided region of the second sub-unit structure arranged in an (n+1)^{th} row and an (m−1)^{th} column; and
the first divided region of the second sub-unit structure arranged in the (n+1)^{th} row and an (m+1)^{th} column,
wherein the unit structure has a third horizontal length in the first direction and a third vertical length in the second direction, and
wherein the third horizontal length and the third vertical length are in a ratio of 1:1.
